(19) United States
(12) Patent Application Publication
(10) Pub. No.: US 2026/0171033 A1
(43) Pub. Date: Jun. 18, 2026

(54) DISPLAY DEVICE AND ELECTRONIC DEVICE INCLUDING THE SAME

(71) Applicant: Samsung Display Co., Ltd., Yongin-si (KR)

(72) Inventors: Mungyu Kim, Yongin-si (KR); GICHANG LEE, Yongin-si (KR); Dongwan Ha, Yongin-si (KR); Junsoo Ko, Yongin-si (KR); Chankeun Kwon, Yongin-si (KR); Hyungseup Kim, Yongin-si (KR); SANG YONG NO, Yongin-si (KR)

(21) Appl. No.: 19/340,669

(22) Filed: Sep. 25, 2025

(30) Foreign Application Priority Data
Dec. 12, 2024 (KR) 10-2024-0184611

(51) Int. Cl. G09G 3/3275; G09G 3/3266; H10K 59/131; H10K 59/80

(52) U.S. Cl. CPC G09G 3/3275; G09G 3/3266; H10K 59/131; H10K 59/871; H10K 59/873; G09G 2300/0426

(57) ABSTRACT

A display device includes a display panel located on a one surface of the transparent substrate and including a display area in which a plurality of pixels configured to emit light is arranged, a non-display area, and a pad area, a driving controller located on the one surface of the transparent substrate, the driving controller being spaced from the display panel, and electrically connected to the display panel, and a plurality of connecting lines extending from the driving controller toward the display panel, and electrically connecting the display panel and the driving controller.

### CROSS-REFERENCE TO RELATED APPLICATION(S)

This application claims priority to and the benefit of Korean Patent Application No. 10-2024-0184611, filed on Dec. 12, 2024, in the Korean Intellectual Property Office, the entire disclosure of which is incorporated by reference herein.

### BACKGROUND

### 1. Field

The present disclosure relates to a display device and an electronic device including the same. More particularly, the present disclosure relates to the display device for implementation of high resolution and the electronic device including the same.

### 2. Description of the Related Art

A display device is a device that displays an image to provide visual information to users. As the information society develops, demand for display devices for displaying images is increasing in various forms. The display device may include a light-emitting element for emitting light to display the image and a pixel circuit for operating the light-emitting element.

Recently, research is being conducted on ultra-small light-emitting elements manufactured by independently growing light-emitting elements on a substrate including silicon and/or glass to implement a high-resolution display device.

### SUMMARY

Embodiments provide a display device in which an arrangement space for a timing controller for high-resolution implementation is secured.

Embodiments provide an electronic device including the display device.

A display device according to one or more embodiments includes a transparent substrate, a display panel, a driving controller, and a plurality of connecting lines. The display panel is located (e.g., formed) on a one surface of the transparent substrate. The display panel includes a display area in which a plurality of pixels configured to emit light is arranged, a non-display area adjacent to the display area, and a pad area adjacent to the non-display area. The driving controller is located on the one surface of the transparent substrate and spaced apart from the display panel. The driving controller is electrically connected to the display panel. The plurality of connecting lines is located on the one surface of the transparent substrate and extends from the driving controller toward the display panel. The plurality of connecting lines are electrically connecting the display panel and the driving controller.

In one or more embodiments, the display panel may include a first source driver and a second source driver. The first source driver may be electrically connected to the driving controller, and located in the non-display area adjacent to one side of the display area. The second source driver electrically may be connected to the driving controller, and located in the non-display area adjacent to an other side of the display area which is opposite to the one side of the display area.

In one or more embodiments, the display device may further include a plurality of first pad electrodes and a plurality of second pad electrodes. The plurality of first pad electrodes may be located on the one surface of the transparent substrate and overlap a portion of the display panel located in the pad area in a plan view. The plurality of first pad electrodes may be electrically connected to the display panel. The plurality of second pad electrodes may be located on the one surface of the transparent substrate and overlap the driving controller in a plan view. The plurality of second pad electrodes may be electrically connected to the driving controller. The plurality of connecting lines may electrically connect the plurality of first pad electrodes and the plurality of second pad electrodes to each other.

In one or more embodiments, the pad area may include a first pad area and a second pad area. The plurality of the first pad electrodes may be located in the first pad area. The second pad area may be spaced from the first pad area, and the display area and the non-display area may be arranged between the first pad area and the second pad area.

In one or more embodiments, the display panel may further include a first gate driver. The first gate driver may be electrically connected to the driving controller and located in the non-display area which is located between the first pad area and the display area in a plan view.

In one or more embodiments, the display panel may further include a second gate driver. The second gate driver may be electrically connected to the driving controller, located in the non-display area which is located between the second pad area and the display area in a plan view, and spaced from the first gate driver.

In one or more embodiments, the display device may further include a plurality of third pad electrodes, a circuit board, a plurality of fourth pad electrodes, a plurality of driving lines, and a power line. The plurality of third pad electrodes may be located on the one surface of the transparent substrate. The plurality of third pad electrodes may overlap a portion of the display panel located in the second pad area. The plurality of third pad electrodes may be electrically connected to the display panel. The circuit board may be located on the one surface of the transparent substrate. The circuit board may be spaced apart from the display panel and the driving controller in a one direction. The plurality of fourth pad electrodes may be located on the one surface of the transparent substrate. The plurality of fourth pad electrodes may overlap the circuit board in a plan view. The plurality of fourth pad electrodes may be electrically connected to the circuit board. The plurality of driving lines may electrically connect the plurality of third pad electrodes and the plurality of fourth pad electrodes to each other. The power line electrically may connect two fourth pad electrodes from among the plurality of fourth pad electrodes to each other, the two fourth pad electrodes being respectively adjacent to one side and an other side of the circuit board. The power line may be configured to provide a first power voltage to the pixels.

In one or more embodiments, the plurality of the driving lines may include a first driving line, a second driving line, and a third driving line. The first driving line may provide a second power voltage having a different voltage level from the first power voltage to the pixels. The second driving line may provide a third power voltage for driving the first source drive and the second source driver. The third driving line may provide a fourth power voltage for driving the first gate driver.

In one or more embodiments, the plurality of the driving lines are spaced from each other in a plan view. Each of the driving lines is around at least a portion of the display panel in a plan view. The power line is around at least a portion of the plurality of driving lines and the display panel in a plan view.

In one or more embodiments, the display device may further include a sealing member and an encapsulation substrate. The sealing member may be located between the display panel and the transparent substrate in a cross-sectional view. The sealing member may surround at least a portion of the display area in a plan view. The encapsulation substrate located between the display panel and the transparent substrate. The encapsulation substrate may be combined with the display panel through the sealing member

A display device according to one or more embodiments includes a transparent substrate, a display panel, a driving controller, and a source driver. The display panel is located on a one surface of the transparent substrate. The display pane includes a display area in which a plurality of pixels emitting light is arranged, a non-display area adjacent to the display area, and a pad area adjacent to the non-display area. The driving controller is located on the one surface of the transparent substrate and spaced apart from the display panel. The driving controller may be electrically connected to the display panel. The source driver is located on the one surface of the transparent substrate and spaced from the display panel in a plan view. The source driver is electrically connected to the display panel and the driving controller.

In one or more embodiments, the source driver may include a first source driver and a second source driver. The first source driver may be located on the one surface of the transparent substrate. The first source driver may be electrically connected to the driving controller. The source driver may be spaced from one side of the display panel. The second source driver may be located on the one surface of the transparent substrate. The second source driver may be electrically connected to the driving controller. The second source driver may be spaced apart from an other side opposite to the one side of the display panel.

In one or more embodiments, the display device may further include a circuit board and a plurality of driving lines. The circuit board may be located on the one surface of the transparent substrate. The circuit board may be electrically connected to the driving controller and the display panel. The plurality of driving lines may be located on the one surface of the transparent substrate. The plurality of driving lines may extend from the circuit board toward the display panel.

In one or more embodiments, the pad area may include a first pad area, a second pad area, and a third pad area. The first pad area may be adjacent to the first source driver. The second pad area may be adjacent to the second source driver. The plurality of driving lines may extend in the third pad area.

In one or more embodiments, the display device may further include a plurality of first connecting lines and a plurality of second connecting lines. The plurality of first connecting lines may be located on the one surface of the transparent substrate. The plurality of first connecting lines may extend from the source driver toward the display panel. The plurality of first connecting lines may electrically connect the display panel and the source driver. The plurality of second connecting lines may be located on the one surface of the transparent substrate. The plurality of second connecting lines may extend from the driving controller toward the display panel. The plurality of second connecting lines may electrically connect the driving controller and the source driver.

In one or more embodiments, the display device may further include a sealing member. The sealing member may be located between the display panel and the transparent substrate in a cross-sectional view. The sealing member may contact the display panel and the transparent substrate.

In one or more embodiments, the display panel may further include a dam structure. The dam structure may be located closer to the display area than the sealing member, in the non-display area.

An electronic device according to one or more embodiments includes a processor and a display device. The processor outputs an input image data and an input control signal. The display device drives based on the input image data and the input control signal. The display device includes a transparent substrate, a display panel, a driving controller, and a plurality of connecting lines. The display panel is located on a one surface of the transparent substrate. The display panel includes a display area in which a plurality of pixels configured to emit light is arranged, a non-display area adjacent to the display area, and a pad area adjacent to the non-display area. The driving controller is located on the one surface of the transparent substrate and spaced from the display panel. The driving controller is electrically connected to the display panel. The plurality of connecting lines is located on the one surface of the transparent substrate and extends from the driving controller toward the display panel. The plurality of connecting lines are electrically connecting the display panel and the driving controller.

In one or more embodiments, the processor is located on the one surface of the transparent substrate.

In the display device according to one or more embodiments of the present disclosure, a driving controller and a display panel may be arranged on the one surface of a transparent substrate. The driving controller and the display panel may be spaced from each other in a plan view, and may be electrically connected to each other through a plurality of connecting lines arranged on the one surface of the transparent substrate. Accordingly, the display device may allow the driving controller to be arranged without a size constraint to achieve high resolution, the display area where pixels are arranged may be reduced, and dead space that causes size constraints in the arrangement of the pixels may be reduced. Accordingly, a deterioration phenomenon generated due to the size constraint of the driving controller may be reduced, and display quality may be improved by implementing the display device with high resolution.

In addition, an encapsulation substrate may not be arranged between the display panel and the transparent substrate, and a sealing member may be arranged between the display panel and the transparent substrate. Accordingly, a thickness of the display device may be less than a display device including the encapsulation substrate. Accordingly, a cost and time in the manufacturing process of the display device may be reduced.

In the electronic device according to one or more embodiments of the present disclosure, a processor for driving the display device may be arranged. In addition, the display device and the processor may be housed. Accordingly, because housing protects the display device that displays an image, a durable electronic device may be provided to user. In addition, since the electronic device further includes a strap portion and a cushion portion worn on a head of the user, a stable wearing feeling maybe provided to the user.

### BRIEF DESCRIPTION OF THE DRAWINGS

Illustrative, non-limiting embodiments will be more clearly understood from the following detailed description in conjunction with the accompanying drawings.

FIG. 1 is a block diagram illustrating a display device according to an embodiment of the present disclosure.

FIG. 2 is a diagram illustrating a circuit diagram of a pixel included in the display device of FIG. 1.

FIG. 3 is a cross-sectional view illustrating a cross-section for explaining a stacked structure of the display device of FIG. 1.

FIG. 4 is a cross-sectional view illustrating a cross-section for explaining a stacked structure of the display panel of FIG. 3.

FIG. 5 is a bottom view illustrating an example of a bottom surface of the display device of FIG. 1.

FIG. 6 is a bottom view illustrating another example of a bottom surface of the display device of FIG. 1.

FIG. 7 is a plan view illustrating an example of a pixel arrangement in the display area of FIG. 5.

FIG. 8 is a plan view illustrating another example of a pixel arrangement in the display area of FIG. 5.

FIG. 9 is a plan view illustrating still another example of a pixel arrangement in the display area of FIG. 5.

FIG. 10 is a plan view illustrating still another example of a pixel arrangement in the display area of FIG. 5.

FIG. 11 is a cross-sectional view illustrating a cross-section taken along line I-I′ of FIG. 5.

FIG. 12 is a cross-sectional view illustrating an enlarged view of an area A1 of FIG. 11.

FIG. 13 is a cross-sectional view illustrating a stacked structure of a display device according to another embodiment of the present disclosure.

FIG. 14 is a bottom view illustrating an example of a bottom surface of the display device of FIG. 13.

FIG. 15 is a bottom view illustrating another example of a bottom surface of the display device of FIG. 13.

FIG. 16 is a cross-sectional view illustrating a cross-section taken along line II-II′ of FIG. 14.

FIG. 17 is a cross-sectional view illustrating an example of an enlarged view of an area A2 of FIG. 16.

FIG. 18 is a cross-sectional view illustrating another example of an enlarged view of an area A2 of FIG. 16.

FIG. 19 is a cross-sectional view illustrating still another example of an enlarged view of an area A2 of FIG. 16.

FIG. 20 is a block diagram illustrating an electronic device according to an embodiment of the present disclosure.

FIG. 21 is a cross-sectional view illustrating a portion of the electronic device of FIG. 20.

FIG. 22 is a diagram illustrating an example in which the electronic device of FIG. 20 is implemented as a smartphone.

FIG. 23 is a diagram illustrating an example in which the electronic device of FIG. 20 is implemented as a head-mounted device.

### DETAILED DESCRIPTION

Hereinafter, display devices in accordance with embodiments will be described in more detail with reference to the accompanying drawings. The same reference numerals are used for the same components in the drawings, and redundant descriptions of the same components will be omitted.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” and/or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” and/or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the drawings.

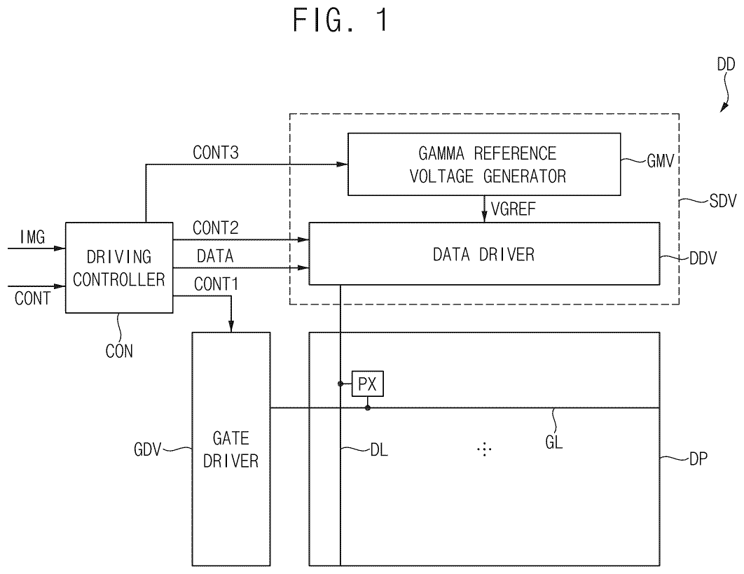

FIG. 1 is a block diagram illustrating a display device according to one or more embodiments of the present disclosure.

Referring to FIG. 1, the display device DD according to one or more embodiments of the present disclosure may include a display panel DP and a display panel driver. The display panel drive may include a driving controller CON, a gate driver GDV, a gamma reference voltage generator GMV, and a data driver DDV.

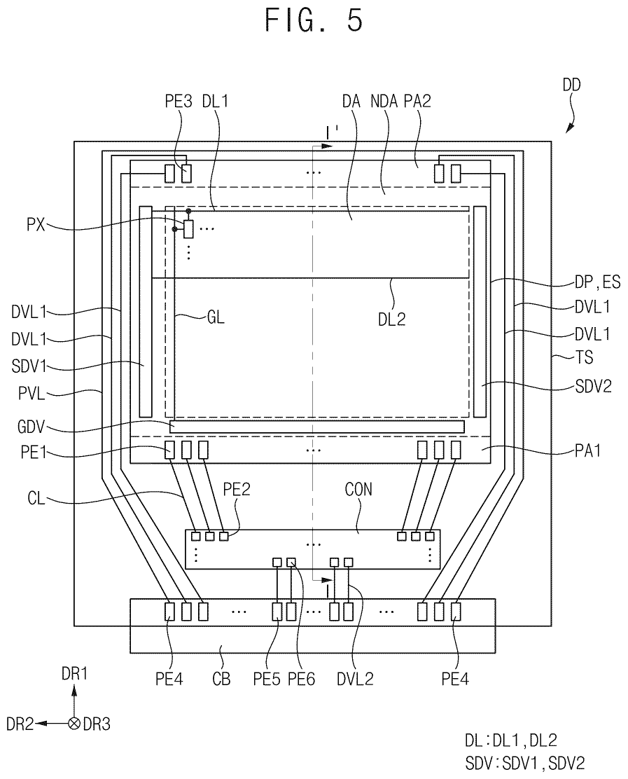

The display panel DP may include a display area (e.g., the display area DA in FIG. 5) defined as an area for displaying an image, and a non-display area, and pad areas adjacent to the display area (e.g., the non-display area NDA, the first pad area PA1, and the second pad area PA2 in FIG. 5). A plurality of pixels PX, a plurality of gate lines GL, and a plurality of data lines DL may be arranged in the display area of the display panel DP. The display panel driver may be arranged in the peripheral area and the pad area of the display panel DP.

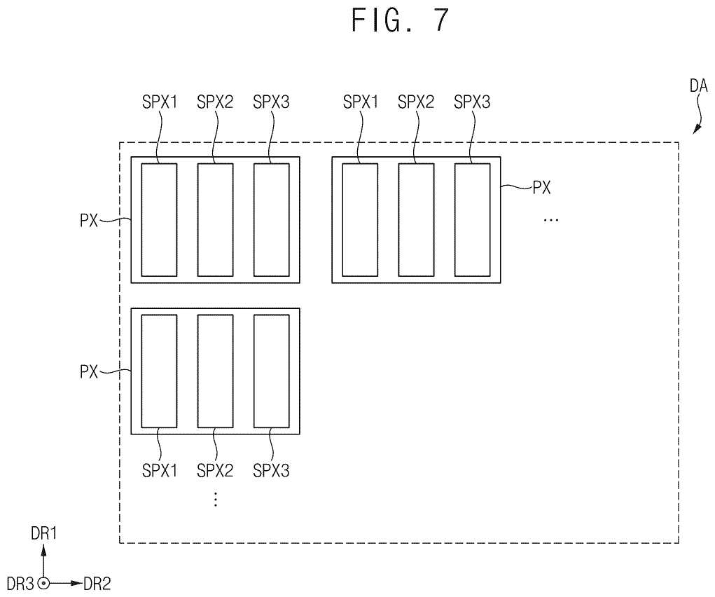

The plurality of pixels PX may be arranged in a matrix form including a plurality of pixel rows and a plurality of pixel columns. For example, the plurality of pixels PX may be arranged along rows and columns of a matrix. One pixel from among the plurality of pixels PX may include sub-pixels that emit light of different colors. For example, one pixel from among the pixels may include a first sub-pixel that emits light of a first color (e.g., a first sub-pixel SPX1 in FIG. 7), a second sub-pixel that emits light of a second color (e.g., a second sub-pixel SPX2 in FIG. 7), and a third sub-pixel that emits light of a third color (e.g., a third sub-pixel SPX3 in FIG. 7).

In one or more embodiments, the light of the first color may be red light, the light of the second color may be green light, and the light of the third color may be blue light. However, colors of light emitted by the first sub-pixel, the second sub-pixel, and the third sub-pixel according to one or more embodiments of the present disclosure may not be limited thereto. For example, the first sub-pixel, the second sub-pixel, and the third sub-pixel may be combined to emit magenta light, cyan light, and/or yellow light.

The plurality of gate lines GL may extend in a one direction. The plurality of data lines DL may extend in another direction crossing the one direction. The plurality of gate lines GL and the plurality of data lines DL may cross each other in a plan view. Each of the plurality of gate lines GL may be spaced (e.g., spaced apart) in a plan view. Each of the plurality of data lines DL may be spaced (e.g., spaced apart) in a plan view.

The driving controller CON may receive input image data IMG and input control signals CONT from an external device (e.g., a processor such as a graphic processing unit GPU).

In one or more embodiments, the input image data IMG may include red image data, green image data, and/or blue image data. In one or more embodiments, the input image data IMG may further include white image data. In another embodiment, the input image data IMG may include magenta image data, yellow image data, and/or cyan image data.

In one or more embodiments, the input control signal CONT may include a master clock signal and a data enable signal. In one or more embodiments, the input control signal CONT may further include a vertical sync signal and a horizontal sync signal.

The driving controller CON may generate a gate control signal CONT1 for controlling the operation of the gate driver GDV based on the input control signal CONT. The driving controller CON may output the gate control signal CONT1 to the gate driver GDV. The gate control signal CONT1 may include a vertical start signal and a gate clock signal.

The driving controller CON may generate a data control signal CONT2 for controlling an operation of the data driver DDV based on the input control signal CONT. The driving controller CON may output the data control signal CONT2 to the data driver DDV. The data control signal CONT2 may include a horizontal start signal and a load signal.

The driving controller CON may generate data signals DATA based on the input image data IMG. Accordingly, the driving controller CON may output the data signals DATA to the data driver DDV.

The driving controller CON may generate a gamma control signal CONT3 for controlling the operation of the gamma reference voltage generator GMV based on the input control signal CONT. The driving controller CON may output the gamma control signal CONT3 to the gamma reference voltage generator GMV.

The gate driver GDV may generate output signals for driving the plurality of gate lines GL in response to the gate control signal CONT1 received from the driving controller CON. In one or more embodiments, the gate driver GDV may be included in the display panel DP. For example, the gate driver GDV may be mounted in the non-display area of the display panel DP. Specifically, the gate driver GDV may be integrated within the non-display area of the display panel DP, and the display panel DP and the gate driver GDV may be integrally formed.

The gamma reference voltage generator GMV may generate a gamma reference voltage VGREF in response to the gamma control signal CONT3 received from the driving controller CON. The gamma reference voltage generator GMV may provide the gamma reference voltage VGREF to the data driver DDV. In one or more embodiments, the gamma reference voltage generator GMV may be integrally formed with the data driver DDV. Accordingly, the gamma reference voltage generator GMV together with the data driver DDV may define a source driver SDV.

The data driver DDV may receive the data control signal CONT2 and the data signal DATA from the driving controller CON. The data driver DDV may receive the gamma reference voltage VGREF from the gamma reference voltage generator GMV. The data driver DDV may convert the data signal DATA into an analog data voltage VDATA using the gamma reference voltage VGREF. The data driver DDV may output the data voltage VDATA to each of the plurality of data lines DL.

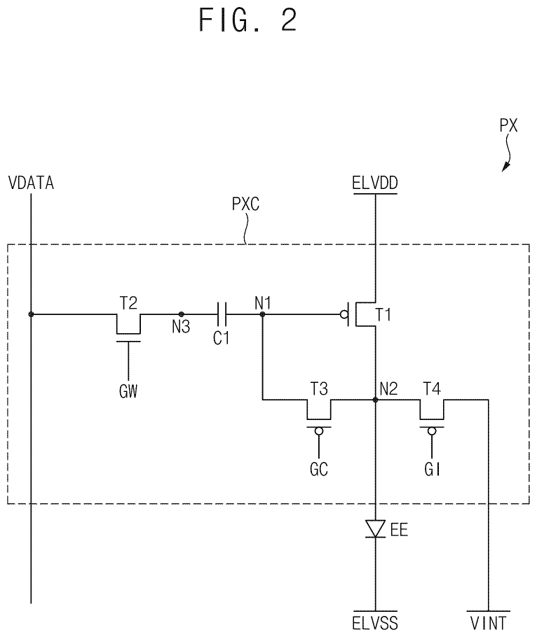

FIG. 2 is a diagram illustrating a circuit diagram of a pixel included in the display device of FIG. 1.

Referring to FIG. 2, one pixel from among the plurality of pixels PX may include a pixel circuit portion PXC and a light-emitting element EE. The pixel circuit portion PXC may include a first transistor T1, a second transistor T2, a third transistor T3, a fourth transistor T4, and a first capacitor C1. The pixel circuit portion PXC may provide a driving current to the light-emitting element EE, and the light-emitting element EE may generate light based on the driving current. The light-emitting element EE may receive a first power supply voltage ELVSS.

The first transistor T1 may include a gate electrode connected to a first node N1, a first electrode to which a second power supply voltage ELVDD is applied, and a second electrode connected to a second node N2. The first transistor T1 may generate the driving current based on a voltage between the first node N1 and the second node N2, that is, the voltage stored in the first capacitor C1. The first transistor T1 may be referred to as a driving transistor for generating the driving current. The first transistor T1 may provide the driving current to the light-emitting element EE.

The second transistor T2 may include a gate electrode for receiving a gate write signal GW, a first electrode connected to a data voltage line, and a second electrode connected to a third node N3. Accordingly, the second transistor T2 may be turned on or off by the gate write signal GW. For example, in response to the gate write signal GW, the second transistor T2 may apply a data voltage VDATA, received from the data voltage line, to the third node N3. The second transistor T2 may be referred to as a write transistor or a scan transistor for transmitting the data voltage VDATA.

The third transistor T3 may include a gate electrode for receiving a gate compensation signal GC, a first electrode connected to the first node N1, and a second electrode connected to the second node N2. Accordingly, the third transistor T3 may be turned on or off by the gate compensation signal GC. For example, in response to the gate compensation signal GC, the third transistor T3 may diode-connect the first node N1 and the second node N2. Accordingly, through the diode-connected structure of the third transistor T3, a threshold voltage of the first transistor T1 may be compensated. Specifically, during the period when the third transistor T3 is turned on by the gate compensation signal GC having an activation level, the threshold voltage of the first transistor T1 may be compensated, allowing each of the plurality of pixels PX to emit light with accurate luminance corresponding to the target. The third transistor T3 may be referred to as a compensation transistor for compensating the threshold voltage of the first transistor T1.

The fourth transistor T4 may include a gate electrode for receiving a gate initialization signal GI, a first electrode to which an initialization voltage VINT is applied, and a second electrode connected to the second node N2. Accordingly, the fourth transistor T4 may be turned on or off by the gate initialization signal GI. For example, in response to the gate initialization signal GI, the fourth transistor T4 may apply the initialization voltage VINT to the second node N2. The fourth transistor T4 may be referred to as an initialization transistor for initializing the second node N2.

The first capacitor C1 may include a first electrode connected to the first node N1 and a second electrode connected to the third node N3. The first capacitor C1 may store the data voltage VDATA transmitted through the second transistor T2. The first capacitor C1 may be referred to as a storage capacitor for storing the data voltage VDATA.

The light-emitting element EE may include a first terminal (e.g., an anode terminal) and a second terminal (e.g., a cathode terminal). The first terminal of the light-emitting element EE may be connected to the second node N2, and the second terminal may be supplied with the second power supply voltage ELVSS. The light-emitting element EE may generate light of luminance corresponding to the driving current.

In one or more embodiments, a voltage level of the first power supply voltage ELVSS may be different from a voltage level of the second power supply voltage ELVDD. For example, a voltage level of the first power supply voltage ELVSS may be less than a voltage level of the second power supply voltage ELVDD. However, a voltage level relationship between the first power supply voltage ELVSS and the second power supply voltage ELVDD according to one or more embodiments of the present disclosure may not be limited thereto.

In one or more embodiments, each of the first, second, third, and fourth transistors T1, T2, T3, and T4 may be PMOS transistors. However, the types of the first, second, third, and fourth transistors T1, T2, T3, and T4 according to one or more embodiments of the present disclosure may not be limited thereto, and at least one transistor from among the first, second, third, and fourth transistors T1, T2, T3, and T4 may be an NMOS transistor.

In FIG. 2, the number of transistors included in one pixel from among the plurality of pixels PX is shown as four, and the number of capacitors is shown as one, but the number of transistors and capacitors included in one pixel according to one or more embodiments of the present disclosure may not be limited thereto. For example, one pixel may include three or fewer or five or more transistors, or one pixel may include two or more capacitors.

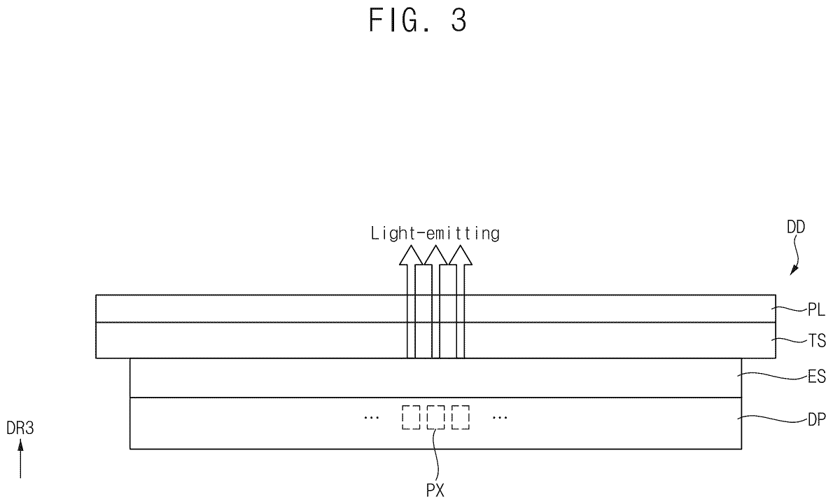

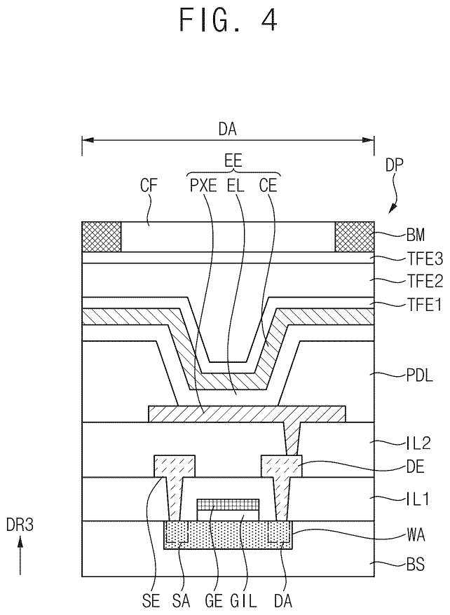

FIG. 3 is a cross-sectional view illustrating a cross-section for explaining a stacked structure of the display device of FIG. 1. FIG. 4 is a cross-sectional view illustrating a cross-section for explaining a stacked structure of the display panel of FIG. 3. FIG. 5 is a bottom view illustrating an example of a bottom surface of the display device of FIG. 1.

Referring to FIGS. 3, 4, and 5, the display panel DP may include a display area DA, a non-display area NDA, a first pad area PA1, and a second pad area PA2. The display panel DP may include a first source driver SDV1 and a second source driver SDV2, which are included in the source driver SDV, and a plurality of first data lines DL1 and a plurality of second data lines DL2, which are included in a plurality of data lines DL. The display device DD may include a plurality of first pad electrodes PE1, a plurality of second pad electrodes PE2, a plurality of third pad electrodes PE3, a plurality of fourth pad electrodes PE4, a plurality of fifth pad electrodes PE5, a plurality of sixth pad electrodes PE6, a power line PVL, a plurality of first driving lines DVL1, a plurality of second driving lines DVL2, a plurality of connecting lines CL, and a circuit board CB.

The non-display area NDA may be adjacent to the display area DA. For example, the non-display area NDA may be around (e.g., may surround) at least a portion of the display area DA along an edge or a periphery of the display area DA. The first pad area PA1 may be spaced (e.g., spaced apart) from the display area DA in a direction opposite to the first direction DR1. The first pad area PA1 may be adjacent to the non-display area NDA. For example, the first pad area PA1 may be adjacent to the non-display area NDA in the direction opposite to the first direction DR1. The second pad area PA2 may be spaced (e.g., spaced apart) from the display area DA in the first direction DR1. The second pad area PA2 may be adjacent to the non-display area NDA. For example, the second pad area PA2 may be adjacent to the non-display area NDA in the first direction DR1. In one or more embodiments, the display area DA and the non-display area NDA may be arranged between the first pad area PA1 and the second pad area PA2.

The display panel DP may include a base substrate BS, a gate insulating layer GIL, a gate electrode GE, a first insulating layer IL1, a source electrode SE, a drain electrode DE, a second insulating layer IL2, a pixel electrode PXE, a pixel defining layer PDL, a light-emitting layer EL, a common electrode CE, a first thin film encapsulation layer TFE1, a second thin film encapsulation layer TFE2, a third thin film encapsulation layer TFE3, a color filter CF, and a light-blocking member BM.

The base substrate BS may include a well area WA, a source area SA, and a drain area DA. The well area WA, the source area SA, and the drain area DA of the base substrate BS, together with the gate electrode GE, the source electrode SE, and the drain electrode DE, may define a transistor. The transistor may be one transistor from among the first, second, third, and fourth transistors T1, T2, T3, and T4 shown in FIG. 2. The pixel electrode PXE, the light-emitting layer EL, and the common electrode CE may define a light-emitting element EE.

In the present disclosure, a plane may be defined by a first direction DR1 and a second direction DR2 that intersects the first direction DR1. For example, the first direction DR1 and the second direction DR2 may be perpendicular to each other. In addition, a third direction DR3 (e.g., a thickness direction of the base substrate BS) may be perpendicular to the plane.

The base substrate BS may serve as the foundation of the display panel DP. In one or more embodiments, the base substrate BS may include a silicon wafer. In one or more embodiments, the well area WA may be adjacent to the source area SA and the drain area DA, and a channel area through which charge carriers move may be defined in the well area WA located between the source area SA and the drain area DA. The well area WA may be a p-well or an n-well. The p-well may refer to a substrate where the charge carriers are holes, and the n-well may refer to a substrate where the charge carriers are electrons.

In one or more embodiments, each of the source area SA and the drain area DA may be adjacent to an edge portion of the well area WA. In one or more embodiments, each of the source area SA and the drain area DA may be a region doped with an n-type or p-type dopant. For example, when the source area SA and the drain area DA are each doped with a p-type dopant, the well area WA may be an n-well. In another example, when the source area SA and the drain area DA are each doped with an n-type dopant, the well area WA may be a p-well. However, the type of the well area WA and the type of dopants doped in the source area SA and the drain area DA, as well as their combinations, are merely illustrative and may not be limited thereto.

A type of the base substrate BS according to one or more embodiments of the present disclosure may not be limited thereto, and an active layer including the source area SA, the drain area DA, and the channel area may further be arranged on the base substrate BS. For example, the base substrate BS may be a transparent resin substrate such as polyimide. Specifically, the polyimide substrate may include a first organic layer, a first barrier layer, a second organic layer, and/or the like. In another example, the base substrate BS may include a quartz substrate (e.g., synthetic quartz substrate, F-doped quartz substrate), a calcium fluoride substrate, a soda-lime glass substrate, a non-alkali glass substrate, and/or the like. These may be used alone or in combination.

The gate insulating layer GIL may be arranged on the base substrate BS. In one or more embodiments, the gate insulating layer GIL may at least partially overlap with the well area WA in a plan view. For example, the gate insulating layer GIL may overlap with the central portion of the well area WA in a plan view (e.g., the gate insulating layer GIL may overlap with the central portion of the well area WA in the third direction DR3), and may not overlap with the edge portions of the well area WA adjacent to the source area SA and the drain area DA in a plan view. In one or more embodiments, the gate insulating layer GIL may not overlap with the source area SA and the drain area DA in a plan view.

In one or more embodiments, the gate insulating layer GIL may include an inorganic insulating material. For example, the inorganic insulating material may include silicon oxide (SiOₓ), silicon nitride (SiNₓ), and/or silicon oxynitride (SiOₓN_{y}). These may be used alone or in combination.

The gate electrode GE may be arranged on the gate insulating layer GIL. The gate electrode GE may at least partially overlap with the well area WA in a plan view. For example, the gate electrode GE may overlap with the central portion of the well area WA in a plan view (e.g., the gate electrode GE may overlap with the central portion of the well area WA in the third direction DR3) and may not overlap with the edge portions of the well area WA adjacent to the source area SA and the drain area DA in a plan view. In one or more embodiments, the gate electrode GE may not overlap with the source area SA and the drain area DA in a plan view. The portion where the gate electrode GE overlaps the well area WA may define the channel area.

In one or more embodiments, the gate electrode GE may include a conductive material. For example, the conductive material may include copper (Cu), titanium (Ti), aluminum (Al), molybdenum (Mo), and/or the like. These may be used alone or in combination.

The first insulating layer IL1 may be arranged on the base substrate BS. For example, the first insulating layer IL1 may cover the gate electrode GE on the base substrate BS. In one or more embodiments, the first insulating layer IL1 may cover the gate electrode GE and provide a substantially flat upper surface. However, the first insulating layer IL1 according to one or more embodiments of the present disclosure may not be limited thereto, and the first insulating layer IL1 may have a substantially uniform thickness following the profile of the gate electrode GE, and may generate a step around the gate electrode GE.

In one or more embodiments, the first insulating layer IL1 may include an inorganic insulating material and/or an organic insulating material. In one or more embodiments, the first insulating layer IL1 may have a single-layer structure or a multi-layer structure. For example, when the first insulating layer IL1 has a multi-layer structure, conductive materials may be arranged between the plurality of layers that define the first insulating layer IL1.

The source electrode SE and the drain electrode DE may be arranged on the first insulating layer IL1. The source electrode SE and the drain electrode DE may be electrically connected to portions of the base substrate BS where the source area SA and the drain area DA are located, respectively. For example, the source electrode SE and the drain electrode DE may extend to the source area SA and the drain area DA, respectively, through contact holes penetrating the first insulating layer IL1 in the thickness direction (e.g., the third direction DR3).

In one or more embodiments, the source electrode SE and the drain electrode DE may include a metal, an alloy, a conductive metal oxide, a conductive metal nitride, and/or a transparent conductive material. These may be used alone or in combination.

The second insulating layer IL2 may be arranged on the first insulating layer IL1. For example, the second insulating layer IL2 may cover the source electrode SE and the drain electrode DE on the first insulating layer IL1. In one or more embodiments, the second insulating layer IL2 may cover the source electrode SE and the drain electrode DE and provide a substantially flat upper surface. However, the second insulating layer IL2 according to one or more embodiments of the present disclosure may not be limited thereto, and the second insulating layer IL2 may have a substantially uniform thickness following the profile of the source electrode SE and the drain electrode DE, and may generate a step around the source electrode SE and the drain electrode DE.

In one or more embodiments, the second insulating layer IL2 may include an organic insulating material. For example, the organic insulating material may include acrylic resin, epoxy resin, polyimide, polyethylene, and/or the like. These may be used alone or in combination.

The pixel electrode PXE may be arranged on the second insulating layer IL2. In one or more embodiments, the pixel electrode PXE may be electrically connected to the drain electrode DE. For example, the pixel electrode PXE may contact the drain electrode DE through a contact hole penetrating the second insulating layer IL2 in the thickness direction (e.g., the third direction DR3). However, the pixel electrode PXE according to one or more embodiments of the present disclosure may not be limited thereto, and the pixel electrode PXE may also contact the source electrode SE through the contact hole.

In addition, the structure of the display panel DP according to one or more embodiments of the present disclosure may not be limited thereto, and a connecting electrode arranged between the pixel electrode PXE and the drain electrode DE, and electrically connecting them, may be further provided.

In one or more embodiments, the pixel electrode PXE may include a metal, an alloy, a conductive metal oxide, a conductive metal nitride, and/or a transparent conductive material. For example, the pixel electrode PXE may include silver Ag and indium tin oxide ITO. These may be used alone or in combination.

The pixel defining layer PDL may be arranged on the second insulating layer IL2. In one or more embodiments, the pixel defining layer PDL may partially cover the pixel electrode PXE. Specifically, a hole that exposes the central portion of the pixel electrode PXE may be defined in the pixel defining layer PDL, and the pixel defining layer PDL may cover the edge portion of the pixel electrode PXE. In one or more embodiments, the pixel defining layer PDL may include an organic insulating material. In one or more embodiments, the pixel defining layer PDL may further include a light-blocking material.

The light-emitting layer EL may be arranged on the pixel electrode PXE. In one or more embodiments, the light-emitting layer EL may be entirely arranged on the pixel electrode PXE and the pixel defining layer PDL. However, the light-emitting layer EL according to one or more embodiments of the present disclosure may not be limited thereto, and the light-emitting layer EL may be arranged in the hole of the pixel defining layer PDL. In one or more embodiments, the light-emitting layer EL may include an organic light-emitting material. The organic light-emitting material may include a low molecular organic compound or a polymer organic compound. However, the present disclosure may not be limited thereto, and the light-emitting layer EL may include materials such as quantum dots.

The common electrode CE may be arranged on the pixel defining layer PDL. In one or more embodiments, the common electrode CE may be arranged on the light-emitting layer EL. In one or more embodiments, the common electrode CE may include a metal, an alloy, a conductive metal oxide, a conductive metal nitride, and/or a transparent conductive material. For example, the common electrode CE may include aluminum (Al), platinum (Pt), silver (Ag), magnesium (Mg), gold (Au), chromium (Cr), tungsten (W), titanium (Ti), and/or the like. These may be used alone or in combination.

The first thin film encapsulation layer TFE1 may be arranged on the common electrode CE. In one or more embodiments, the first thin film encapsulation layer TFE1 may have a substantially uniform thickness following the profile of the common electrode CE. In one or more embodiments, the first thin film encapsulation layer TFE1 may include an inorganic insulating material. For example, the inorganic insulating material may include silicon nitride, silicon oxide, silicon oxynitride, and/or the like. These may be used alone or in combination.

The second thin film encapsulation layer TFE2 may be arranged on the first thin film encapsulation layer TFE1. The second thin film encapsulation layer TFE2 may provide a substantially flat upper surface without generating a step around the first thin film encapsulation layer TFE1. In one or more embodiments, the second thin film encapsulation layer TFE2 may include an organic insulating material. For example, the organic insulating material may include acrylic resin, epoxy resin, polyimide, polyethylene, and/or the like. These may be used alone or in combination.

The third thin film encapsulation layer TFE3 may be arranged on the second thin film encapsulation layer TFE2. The third thin film encapsulation layer TFE3 may have a substantially uniform thickness and a substantially flat upper surface. In one or more embodiments, the third thin film encapsulation layer TFE3 may include an inorganic insulating material. For example, the inorganic insulating material may include silicon nitride, silicon oxide, silicon oxynitride, and/or the like. These may be used alone or in combination.

The first to third thin film encapsulation layers TFE1, TFE2, and TFE3 may seal the display area DA of the display panel DP and protect the light-emitting element EE from external impurities.

The color filter CF may be arranged on the third encapsulation layer TFE3. The color filter CF may allow only light having a specific wavelength to pass through. For example, the color filter CF may include a first color filter that transmits light of a first color, a second color filter that transmits light of a second color, and a third color filter that transmits light of a third color. The first, second, and third color filters may be repeatedly arranged along the first direction DR1 and the second direction DR2.

The light-blocking member BM may be arranged on the third encapsulation layer TFE3. The light-blocking member BM may be arranged with the color filter CF interposed therebetween. In one or more embodiments, the light-blocking member BM and the color filter CF may be repeatedly arranged along the first direction DR1 and the second direction DR2. Specifically, the light-blocking member BM may be arranged in a plan view between the first color filter and the second color filter. The light-blocking member BM may also be arranged between the second color filter and the third color filter, or between the first color filter and the third color filter in a plan view.

The light-blocking member BM may block light of different colors and may prevent color mixing between adjacent color filters. In one or more embodiments, the light-blocking member BM may include a light-blocking material. For example, the light-blocking material may include carbon black, organic pigments, and/or the like.

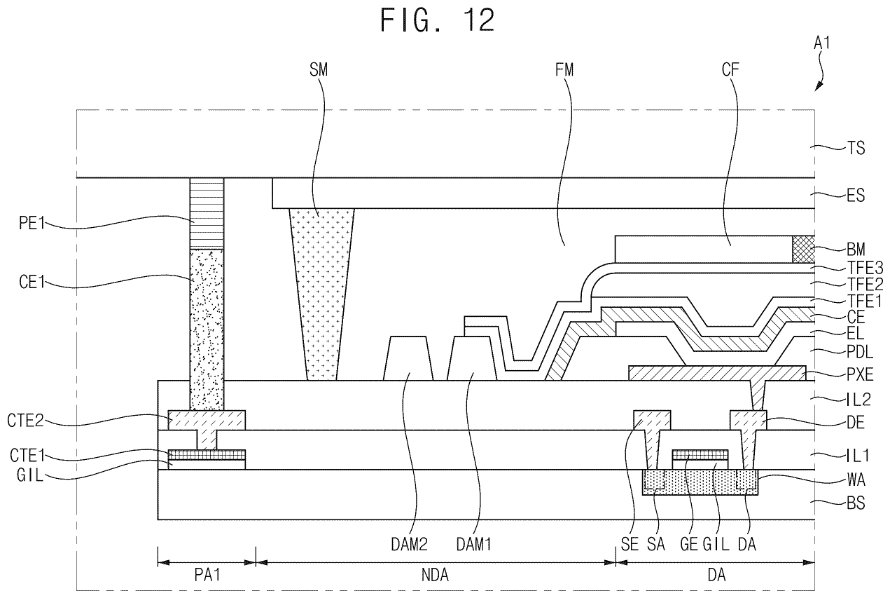

The encapsulation substrate ES may be arranged on the color filter CF and the light-blocking member BM. In one or more embodiments, in a cross-sectional view, a filler member and a sealing member (e.g., the filler member FM and the sealing member SM in FIG. 12) may be arranged between the encapsulation substrate ES and the color filter CF and the light-blocking member BM. The filler member and the sealing member may be arranged in the non-display area NDA, the first pad area PA1, and the second pad area PA2.

In one or more embodiments, the encapsulation substrate ES may include a quartz substrate (e.g., synthetic quartz substrate, F-doped quartz substrate), a calcium fluoride substrate, a soda-lime glass substrate, a non-alkali glass substrate, and/or the like. These may be used alone or in combination.

The transparent substrate TS may be arranged on the encapsulation substrate ES. In one or more embodiments, one surface (e.g., the back surface) of the transparent substrate TS may have the display panel DP and the encapsulation substrate ES arranged thereon. In one or more embodiments, the display panel DP may be arranged on the one surface of the transparent substrate TS. In one or more embodiments, the driving controller CON may be arranged on the one surface of the transparent substrate TS. Specifically, the display panel DP and the driving controller CON may be mounted on the one surface of the transparent substrate TS.

At least a portion of the transparent substrate TS may be transparent. For example, an area corresponding to the display area DA of the transparent substrate TS may be transparent, and areas other than the display area DA (e.g., the non-display area NDA, the first pad area PA1, the second pad area PA2, and a portion of the transparent substrate TS that does not overlap the display panel DP) may be opaque or transparent. However, the transparent substrate TS according to one or more embodiments of the present disclosure may not be limited thereto, and at least a portion of the area corresponding to the display area DA of the transparent substrate TS may be opaque.

The protective layer PL may be arranged on the transparent substrate TS. In one or more embodiments, the protective layer PL may be arranged on the opposite surface (e.g., top surface) of the one surface of the transparent substrate TS. The protective layer PL may be a layer for protecting the display panel DP, the encapsulation substrate ES, and the transparent substrate TS. However, the structure of the display device DD according to one or more embodiments of the present disclosure may not be limited thereto, and a polarizing layer may be arranged between the protective layer PL and the transparent substrate TS, and the color filter CF may not be arranged within the display panel DP.

The plurality of first pad electrodes PE1 may be arranged on the one surface of the transparent substrate TS. For example, the plurality of first pad electrodes PE1 may be arranged in the first pad area PA1 on the one surface of the transparent substrate TS. In one or more embodiments, each of the plurality of first pad electrodes PE1 may be spaced (e.g., spaced apart) from each other in a plan view. Specifically, the plurality of first pad electrodes PE1 may be spaced (e.g., spaced apart) along the second direction DR2 and may be arranged along the second direction DR2.

In one or more embodiments, the plurality of first pad electrodes PE1 may be electrically connected to the display panel DP. For example, the plurality of first pad electrodes PE1 may protrude toward the display panel DP on the one surface of the transparent substrate TS and may be electrically connected to conductive layers arranged in (e.g., at) a same layer as the gate electrode GE or the source and drain electrodes SE, DE within the display panel DP. The plurality of first pad electrodes PE1 may be electrodes configured to be electrically connected to the driving controller CON arranged on the one surface of the transparent substrate TS.

In one or more embodiments, each of the plurality of first pad electrodes PE1 may include a conductive material. For example, each of the plurality of first pad electrodes PE1 may be a copper filler (Cu filler). However, the type of each of the plurality of first pad electrodes PE1 according to one or more embodiments of the present disclosure may not be limited thereto.

A plurality of second pad electrodes PE2 may be arranged on the one surface of the transparent substrate TS. For example, the plurality of second pad electrodes PE2 may be spaced (e.g., spaced apart) from the display panel DP on the transparent substrate TS. The plurality of second pad electrodes PE2 may be located in a direction opposite to the first direction DR1 from the display panel DP. The plurality of second pad electrodes PE2 may overlap the driving controller CON in a plan view.

In one or more embodiments, each of the plurality of second pad electrodes PE2 may be spaced (e.g., spaced apart) from each another in a plan view. Specifically, the plurality of second pad electrodes PE2 may be spaced (e.g., spaced apart) along the second direction DR2 and may be arranged along the second direction DR2. In one or more embodiments, the plurality of second pad electrodes PE2 may be electrically connected to the driving controller CON. The plurality of second pad electrodes PE2 may be electrodes configured to be electrically connected to the display panel DP arranged on the one surface of the transparent substrate TS by the driving controller CON.

A plurality of connecting lines CL may be arranged on the one surface of the transparent substrate TS. In one or more embodiments, the plurality of connecting lines CL may extend in a plan view from the driving controller CON toward the display panel DP. For example, the plurality of connecting lines CL may electrically connect the plurality of first pad electrodes PE1 and the plurality of second pad electrodes PE2. Accordingly, signals for driving the first and second source drivers SDV1, SDV2 and the gate driver GDV may be provided from the driving controller CON through the plurality of connecting lines CL. Specifically, the plurality of first pad electrodes PE1 receiving the signals may be electrically connected to the first source driver SDV1, the second source driver SDV2, and the gate driver GDV. For example, the signals may include a gate control signal, a data control signal, a data signal, and a gamma control signal (e.g., the gate control signal CONT1, data control signal CONT2, data signal DATA, and gamma control signal CONT3 in FIG. 1). However, the types of signals provided through the plurality of connecting lines CL according to one or more embodiments of the present disclosure may not be limited thereto.

The circuit board CB may be arranged on the one surface of the transparent substrate TS. For example, the circuit board CB may be mounted on the one surface of the transparent substrate TS. In one or more embodiments, the circuit board CB may be a flexible circuit board (FPCB) having conductivity. However, the circuit board CB according to one or more embodiments of the present disclosure may not be limited thereto, and the circuit board CB may be a rigid substrate having stiffness.

In one or more embodiments, the circuit board CB may partially overlap with the transparent substrate TS in a plan view. The circuit board CB may receive signals for the driving controller CON from an external device such as a processor. For example, the signals provided to the driving controller CON may include input image data, a master clock signal, a data enable signal as input control signals (e.g., the input image data IMG and the input control signal CONT in FIG. 1), and a main power supply signal.

A plurality of third pad electrodes PE3 may be arranged on the one surface of the transparent substrate TS. For example, the plurality of third pad electrodes PE3 may be arranged in the second pad area PA2 on the one surface of the transparent substrate TS. In one or more embodiments, each of the plurality of third pad electrodes PE3 may be spaced (e.g., spaced apart) from each other in a plan view. Specifically, the plurality of third pad electrodes PE3 may be spaced (e.g., spaced apart) along the second direction DR2 and arranged along the second direction DR2.

In one or more embodiments, the plurality of third pad electrodes PE3 may be electrically connected to the display panel DP. For example, the plurality of third pad electrodes PE3 may protrude toward the display panel DP on the one surface of the transparent substrate TS and may be electrically connected to conductive layers arranged in (e.g., at) a same layer as the gate electrode GE or the source and drain electrodes SE, DE within the display panel DP. The plurality of third pad electrodes PE3 may be electrodes configured to be electrically connected to the circuit board CB arranged on the one surface of the transparent substrate TS.

In one or more embodiments, each of the plurality of third pad electrodes PE3 may include a conductive material. For example, each of the plurality of third pad electrodes PE3 may be a copper filler (Cu filler). In one or more embodiments, the plurality of third pad electrodes PE3 may include a same material as the plurality of first pad electrodes PE1 and may be formed through a same process. However, the type of each of the plurality of third pad electrodes PE3 and the relationship between the first pad electrodes PE1 and the third pad electrodes PE3 according to one or more embodiments of the present disclosure may not be limited thereto.

A plurality of fourth pad electrodes PE4 may be arranged on the one surface of the transparent substrate TS. For example, the plurality of fourth pad electrodes PE4 may overlap the circuit board CB in a plan view on the one surface of the transparent substrate TS. In one or more embodiments, the plurality of fourth pad electrodes PE4 may be electrically connected to the circuit board CB. The plurality of fourth pad electrodes PE4 may be electrodes configured to be electrically connected to the display panel DP arranged on the one surface of the transparent substrate TS.

In one or more embodiments, each of the plurality of fourth pad electrodes PE4 may be spaced (e.g., spaced apart) from each other in a plan view. Specifically, the plurality of fourth pad electrodes PE4 may be spaced (e.g., spaced apart) along the second direction DR2 and arranged along the second direction DR2.

A power line PVL may be arranged on the one surface of the transparent substrate TS. The power line PVL may electrically connect two fourth pad electrodes PE4 that are adjacent to both ends of the circuit board CB. Specifically, the power line PVL may extend from a fourth pad electrode adjacent to a first end located in the direction opposite to the second direction DR2 of the circuit board CB to a fourth pad electrode adjacent to a second end located in the second direction DR2 of the circuit board CB. In one or more embodiments, the power line PVL may be around (e.g., may surround) at least a portion of the display panel DP in a plan view. In one or more embodiments, the power line PVL may be supplied with a first power supply voltage (e.g., the first power supply voltage ELVSS in FIG. 2).

A plurality of first driving lines DVL1 may be arranged on the one surface of the transparent substrate TS. In one or more embodiments, the plurality of first driving lines DVL1 may extend from the circuit board CB toward the display panel DP. Specifically, the plurality of first driving lines DVL1 may extend toward the second pad area PA2 of the display panel DP.

The plurality of first driving lines DVL1 may electrically connect the plurality of third pad electrodes PE3 and the plurality of fourth pad electrodes PE4. For example, each of the plurality of first driving lines DVL1 may extend from one third pad electrode from among the third pad electrodes PE3 to one fourth pad electrode from among the fourth pad electrodes PE4. In one or more embodiments, the power line PVL may be around (e.g., may surround) at least a portion of the plurality of first driving lines DVL1 in a plan view.

The plurality of first driving lines DVL1 may be supplied with a second power supply voltage having a voltage level different from the first power supply voltage (e.g., the second power supply voltage ELVDD in FIG. 2), a third power supply voltage for driving the source driver SDV, and a fourth power supply voltage for driving the gate driver GDV. For example, the plurality of first driving lines DVL1 may include a first-first driving line to which the second power supply voltage is applied, a first-second driving line to which the third power supply voltage for driving the source driver SDV is applied, and a first-third driving line to which the fourth power supply voltage for driving the gate driver GDV is applied. In one or more embodiments, the third power supply voltage may include a high power supply voltage and a low power supply voltage provided within the source driver SDV, and the fourth power supply voltage may be a high power supply voltage and a low power supply voltage provided within the gate driver GDV. However, the types of voltages and signals applied to the plurality of first driving lines DVL1 and classifications or types of the included lines according to one or more embodiments of the present disclosure may not be limited thereto. In this disclosure, the plurality of first driving lines DVL1 may be referred to as a plurality of driving lines, the first-first driving line may be referred to as a first driving line, the first-second driving line may be referred to as a second driving line, and the first-third driving line may be referred to as a third driving line.

In one or more embodiments, the third and fourth power supply voltages received from the first driving lines DVL1 may be provided to the source driver SDV and the gate driver GDV through the third pad electrodes PE3. For example, the third pad electrodes PE3 may be electrically connected to each of the first source driver SDV1, the second source driver SDV2, and the gate driver GDV.

A plurality of fifth pad electrodes PE5 may be arranged on the one surface of the transparent substrate TS. For example, the plurality of fifth pad electrodes PE5 may overlap the circuit board CB in a plan view on the one surface of the transparent substrate TS. In one or more embodiments, the plurality of fifth pad electrodes PE5 may be electrically connected to the circuit board CB. The plurality of fifth pad electrodes PE5 may be electrodes configured to be electrically connected to the driving controller CON arranged on the one surface of the transparent substrate TS.

In one or more embodiments, each of the plurality of fifth pad electrodes PE5 may be spaced (e.g., spaced apart) from each other in a plan view. Specifically, the plurality of fifth pad electrodes PE5 may be spaced (e.g., spaced apart) along the second direction DR2 and arranged along the second direction DR2. In one or more embodiments, the plurality of fifth pad electrodes PE5 may be arranged between the plurality of fourth pad electrodes PE4 in a plan view.

A plurality of sixth pad electrodes PE6 may be arranged on the one surface of the transparent substrate TS. For example, the plurality of sixth pad electrodes PE6 may overlap the driving controller CON in a plan view on the one surface of the transparent substrate TS. In one or more embodiments, the plurality of sixth pad electrodes PE6 may be electrically connected to the driving controller CON. The plurality of sixth pad electrodes PE6 may be electrodes configured to be electrically connected to the circuit board CB arranged on the one surface of the transparent substrate TS.

In one or more embodiments, each of the plurality of sixth pad electrodes PE6 may be spaced (e.g., spaced apart) from each other in a plan view. Specifically, the plurality of sixth pad electrodes PE6 may be spaced (e.g., spaced apart) along the second direction DR2 and arranged along the second direction DR2.

A plurality of second driving lines DVL2 may be arranged on the one surface of the transparent substrate TS. In one or more embodiments, the plurality of second driving lines DVL2 may extend from the circuit board CB toward the driving controller CON. In one or more embodiments, the plurality of second driving lines DVL2 may electrically connect the plurality of fifth pad electrodes PE5 and the plurality of sixth pad electrodes PE6.

In one or more embodiments, input image data and the input control signal delivered from the circuit board CB may be applied to the driving controller CON via the plurality of second driving lines DVL2.

In the display area DA, a plurality of pixels PX, a plurality of first data lines DL1, a plurality of second data lines DL2, and a plurality of gate lines GL may be arranged. In the non-display area NDA, the first source driver SDV1, the second source driver SDV2, and the gate driver GDV may be arranged.

In one or more embodiments, the first source driver SDV1 may extend along the first direction DR1. In one or more embodiments, the first source driver SDV1 may be arranged in the non-display area NDA adjacent to one side of the display area DA. For example, the first source driver SDV1 may be spaced (e.g., spaced apart) from one side of the display area DA in the second direction DR2 in a plan view.

In one or more embodiments, the second source driver SDV2 may extend along the first direction DR1. In one or more embodiments, the second source driver SDV2 may be arranged in the non-display area NDA adjacent to the other side of the display area DA opposite to the one side. For example, the second source driver SDV2 may be spaced (e.g., spaced apart) from the other side of the display area DA in the direction opposite to the second direction DR2 in a plan view.

In one or more embodiments, each of the first data lines DL1 may extend from the first source driver SDV1. Specifically, each of the first data lines DL1 may extend from the first source driver SDV1 in the direction opposite to the second direction DR2 and may be electrically connected to each of the plurality of pixels PX arranged in the display area DA.

In one or more embodiments, each of the second data lines DL2 may extend from the second source driver SDV2. Specifically, each of the second data lines DL2 may extend from the second source driver SDV2 in the second direction DR2 and may be electrically connected to each of the plurality of pixels PX arranged in the display area DA. However, the connecting relationship between the data lines DL and the first and second source drivers SDV1 and SDV2 according to one or more embodiments of the present disclosure may not be limited thereto. For example, each of the first data lines DL1 and the second data lines DL2 may be connected to both the first and second source drivers SDV1 and SDV2.

In one or more embodiments, the gate driver GDV may extend along the second direction DR2. In one or more embodiments, the gate driver GDV may be spaced (e.g., spaced apart) from the display area DA in the direction opposite to the first direction DR1 in a plan view. For example, the gate driver GDV may be arranged between the first pad area PA1 and the display area DA in a plan view. In one or more embodiments, each of the plurality of gate lines GL may extend from the gate driver GDV in the first direction DR1. However, the arrangement of the gate driver GDV and the extension direction of each of the plurality of gate lines GL according to one or more embodiments of the present disclosure may not be limited thereto. For example, the gate driver GDV may be arranged between the second pad area PA2 and the display area DA in a plan view, and each of the plurality of gate lines GL may extend from the gate driver GDV in the direction opposite to the first direction DR1.

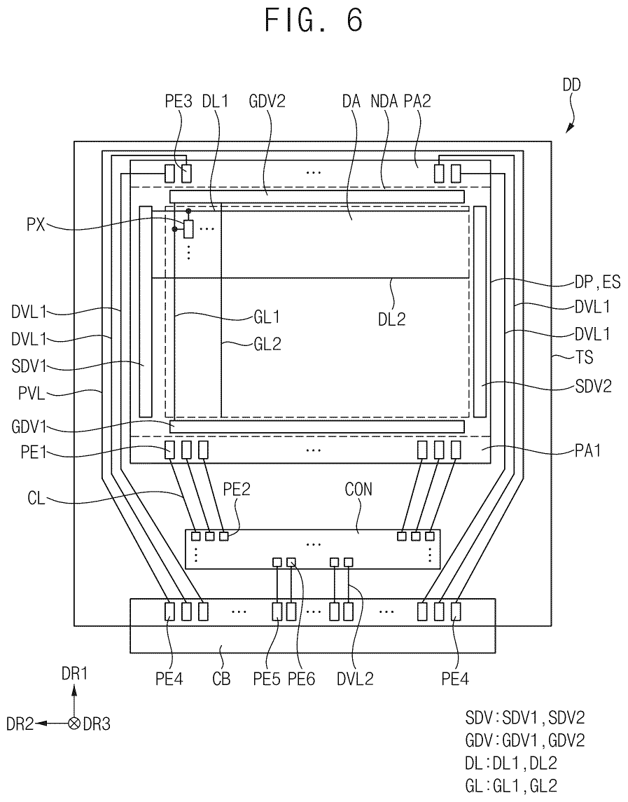

FIG. 6 is a bottom view illustrating another example of a bottom surface of the display device of FIG. 1.

Referring to FIG. 6, a display device DD may be substantially a same as or similar to the display device DD described with reference to FIG. 5, except for a first gate driver GDV1, a second gate driver GDV2, a plurality of first gate lines GL1, and a plurality of second gate lines GL2. Hereinafter, descriptions that overlap with those described with reference to FIG. 5 may be omitted or briefly explained.

Referring to FIG. 6, the gate driver GDV of the display panel DP may include a first gate driver GDV1 and a second gate driver GDV2. In one or more embodiments, the first gate driver GDV1 and the second gate driver GDV2 may be spaced (e.g., spaced apart) from each other in a plan view. Specifically, the first gate driver GDV1 may be arranged in a non-display area DA located between a first pad area PA1 and a display area DA in a plan view. The second gate driver GDV2 may be arranged in a non-display area DA located between a second pad area PA2 and the display area DA in a plan view.

The plurality of gate lines GL of the display panel DP may include a plurality of first gate lines GL1 and a plurality of second gate lines GL2. The plurality of first gate lines GL1 and the plurality of second gate lines GL2 may be spaced (e.g., spaced apart) from each other in a second direction DR2. In one or more embodiments, one first gate line from among the plurality of first gate lines GL1 and one second gate line from among the plurality of second gate lines GL2 may be alternately arranged along the second direction DR2.

In one or more embodiments, each of the plurality of first gate lines GL1 may be electrically connected to the first gate driver GDV1. For example, each of the plurality of first gate lines GL1 may extend from the first gate driver GDV1 in a first direction DR1 and may be electrically connected to each of a plurality of pixels PX. In one or more embodiments, each of the plurality of second gate lines GL2 may be electrically connected to the second gate driver GDV2. For example, each of the plurality of second gate lines GL2 may extend from the second gate driver GDV2 in a direction opposite to the first direction DR1 and may be electrically connected to each of the plurality of pixels PX.

In one or more embodiments, a gate signal output to each of the plurality of pixels PX from the first gate driver GDV1 may be different from a gate signal output to each of the plurality of pixels PX from the second gate driver GDV2. For example, when the gate signal output from the first gate driver GDV1 and the gate signal output from the second gate driver GDV2 are a same, a single pixel may not be concurrently (e.g., simultaneously) connected to both the first gate line GL1 and the second gate line GL2.

In another embodiment, the gate signal output to each of the plurality of pixels PX from the first gate driver GDV1 may be the same as the gate signal output to each of the plurality of pixels PX from the second gate driver GDV2. When the gate signal output from the first gate driver GDV1 and the gate signal output from the second gate driver GDV2 are different from each other, a single pixel may be concurrently (e.g., simultaneously) connected to both the first gate line GL1 and the second gate line GL2.

However, relationship of the signals output from the first gate driver GDV1 and the second gate driver GDV2 according to one or more embodiments of the present disclosure and the connecting relationship among the plurality of first gate lines GL1, the plurality of second gate lines GL2, and the plurality of pixels PX may not be limited thereto.

In one or more embodiments, the first pad electrodes PE1 may be electrically connected to each of the first source driver SDV1, the second source driver SDV2, the first gate driver GDV1, and the second gate driver GDV2. In one or more embodiments, the third pad electrodes PE3 may be electrically connected to each of the first source driver SDV1, the second source driver SDV2, the first gate driver GDV1, and the second gate driver GDV2.

FIG. 7 is a plan view illustrating an example of a pixel arrangement in the display area of FIG. 5.

According to FIG. 7, one pixel from among the plurality of pixels PX in the display area DA may include a first sub-pixel SPX1 that emits light of a first color, a second sub-pixel SPX2 that emits light of a second color, and a third sub-pixel SPX3 that emits light of a third color. In one or more embodiments, in the display area DA, the first sub-pixel SPX1, the second sub-pixel SPX2, and the third sub-pixel SPX3 may be sequentially arranged along a second direction DR2. For example, a plurality of sets each consisted of the first sub-pixel SPX1, the second sub-pixel SPX2, and the third sub-pixel SPX3 as one set may be repeatedly arranged along the second direction DR2.

In one or more embodiments, sub-pixels that emit light of a same color may be repeatedly arranged along the first direction DR1. For example, a plurality of first sub-pixels SPX1, each emitting the first color light, may be repeatedly arranged along the first direction DR1. For example, a plurality of second sub-pixels SPX2, each emitting the second color light, may be repeatedly arranged along the first direction DR1. For example, a plurality of third sub-pixels SPX3, each emitting the third color light, may be repeatedly arranged along the first direction DR1. However, the arrangement, shape, size, and/or the color of light emitted by the sub-pixels according to one or more embodiments of the present disclosure are merely illustrative and may not be limited thereto.

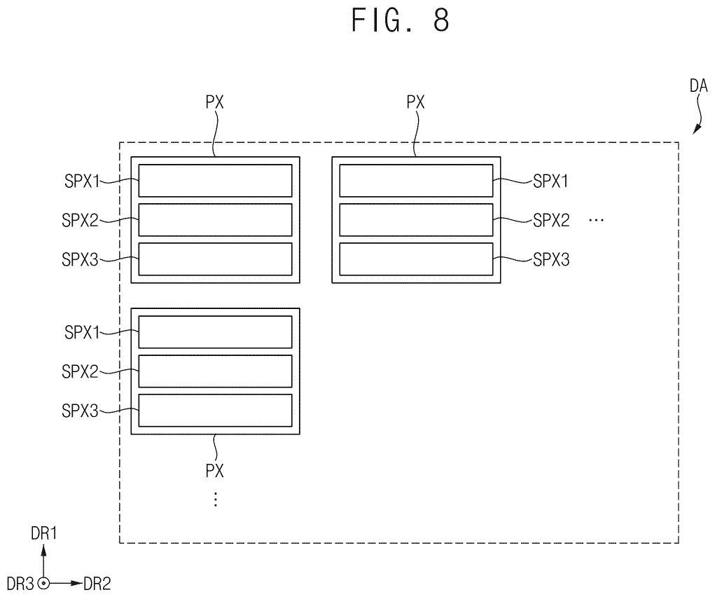

FIG. 8 is a plan view illustrating another example of a pixel arrangement in the display area of FIG. 5.

Referring to FIG. 8, in one or more embodiments, the first sub-pixel SPX1, the second sub-pixel SPX2, and the third sub-pixel SPX3 may be sequentially arranged along the first direction DR1 in the display area DA. For example, a plurality of sets each consisted of the first sub-pixel SPX1, the second sub-pixel SPX2, and the third sub-pixel SPX3 as one set may be repeatedly arranged along the first direction DR1.

In one or more embodiments, sub-pixels that emit light of a same color may be repeatedly arranged along a second direction DR2. For example, a plurality of first sub-pixels SPX1, each emitting the first color light, may be repeatedly arranged along the second direction DR2. For example, a plurality of second sub-pixels SPX2, each emitting the second color light, may be repeatedly arranged along the second direction DR2. For example, a plurality of third sub-pixels SPX3, each emitting the third color light, may be repeatedly arranged along the second direction DR2. However, the arrangement, shape, size, and/or the color of light emitted by the sub-pixels according to one or more embodiments of the present disclosure are illustrative and may not be limited thereto.

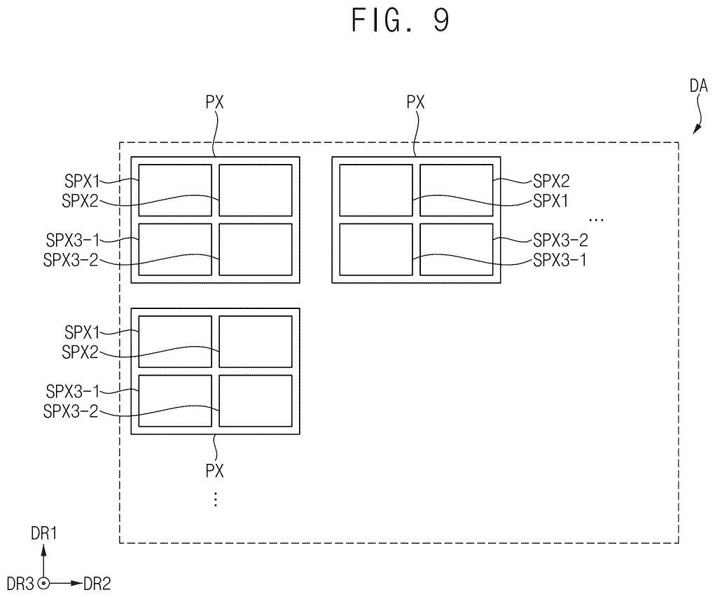

FIG. 9 is a plan view illustrating still another example of a pixel arrangement in the display area of FIG. 5.

Referring to FIG. 9, one among the plurality of pixels PX in the display area DA may include a first sub-pixel SPX1 that emits light of a first color, a second sub-pixel SPX2 that emits light of a second color, a third-first sub-pixel SPX3-1 that emits light of a third color, and a third-second sub-pixel SPX3-2 that emits light of the third color.

In one or more embodiments, in the display area DA, the first sub-pixel SPX1 and the second sub-pixel SPX2 may be alternately arranged along the second direction DR2. In one or more embodiments, the third-first sub-pixel SPX3-1 and the third-second sub-pixel SPX3-2 may also be alternately arranged along the second direction DR2 in the display area DA. For example, the row in which the first sub-pixel SPX1 and the second sub-pixel SPX2 are arranged and the row in which the third-first sub-pixel SPX3-1 and the third-second sub-pixel SPX3-2 are arranged may be adjacent to each other in the first direction DR1.

In one or more embodiments, in the display area DA, the first sub-pixel SPX1 and the third-first sub-pixel SPX3-1 may be alternately arranged along the first direction DR1. In one or more embodiments, the second sub-pixel SPX2 and the third-second sub-pixel SPX3-2 may be alternately arranged along the first direction DR1 in the display area DA. For example, the column in which the first sub-pixel SPX1 and the third-first sub-pixel SPX3-1 are arranged and the column in which the second sub-pixel SPX2 and the third-second sub-pixel SPX3-2 are arranged may be adjacent to each other in the second direction DR2. However, the arrangement, shape, size, and the color of light emitted by the sub-pixels according to one or more embodiments of the present disclosure are illustrative and may not be limited thereto.

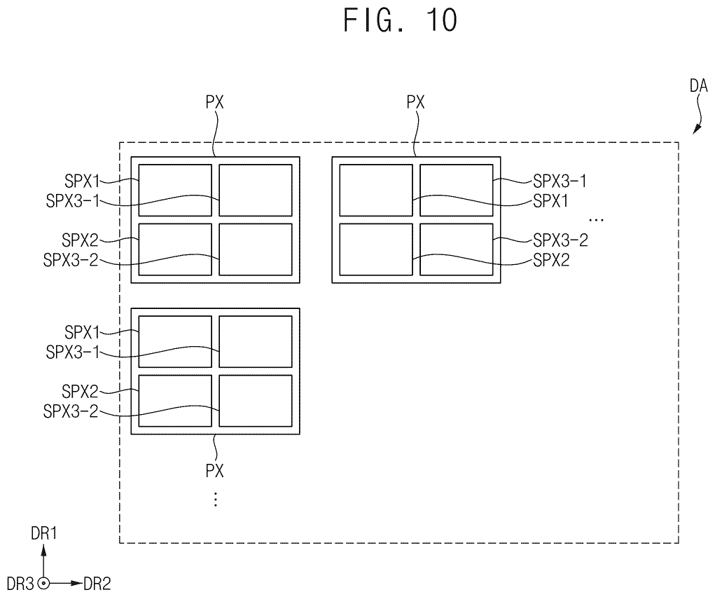

FIG. 10 is a plan view illustrating still another example of a pixel arrangement in the display area of FIG. 5.

Referring to FIG. 10, in one or more embodiments, the first sub-pixel SPX1 and the second sub-pixel SPX2 may be alternately arranged along the first direction DR1 in the display area DA. In one or more embodiments, the third-first sub-pixel SPX3-1 and the third-second sub-pixel SPX3-2 may be alternately arranged along the first direction DR1 in the display area DA. For example, the column in which the first sub-pixel SPX1 and the second sub-pixel SPX2 are arranged and the column in which the third-first sub-pixel SPX3-1 and the third-second sub-pixel SPX3-2 are arranged may be adjacent to each other in the second direction DR2.

In one or more embodiments, in the display area DA, the first sub-pixel SPX1 and the third-first sub-pixel SPX3-1 may be alternately arranged along the second direction DR2. In one or more embodiments, the second sub-pixel SPX2 and the third-second sub-pixel SPX3-2 may be alternately arranged along the second direction DR2 in the display area DA. For example, the row in which the first sub-pixel SPX1 and the third-first sub-pixel SPX3-1 are arranged and the row in which the second sub-pixel SPX2 and the third-second sub-pixel SPX3-2 are arranged may be adjacent to each other in the first direction DR1. However, the arrangement, shape, size, and/or the color of light emitted by the sub-pixels according to one or more embodiments of the present disclosure are illustrative and may not be limited thereto.

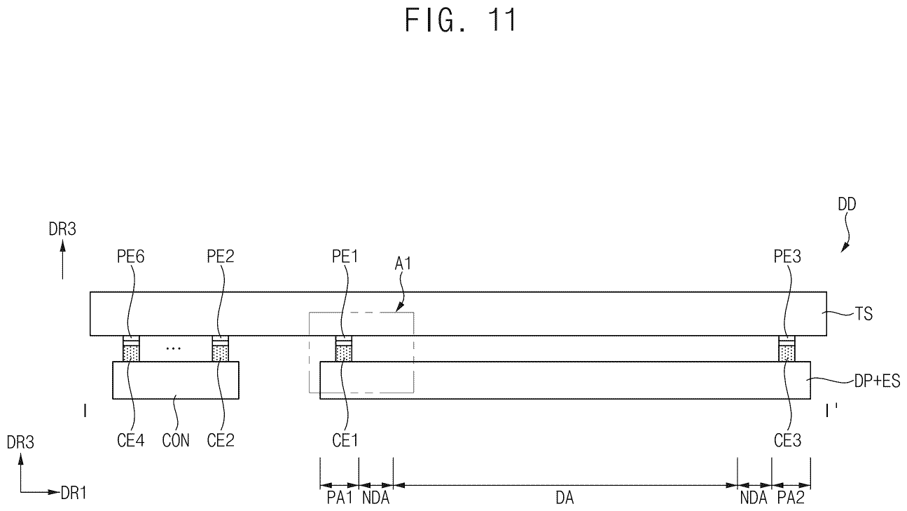

FIG. 11 is a cross-sectional view illustrating a cross-section taken along the line I-I′ of FIG. 5. FIG. 12 is a cross-sectional view illustrating an enlarged view of an area A1 of FIG. 11.

Referring to FIGS. 11 and 12, the display device DD may include a plurality of first connecting electrodes CE1, a plurality of second connecting electrodes CE2, a plurality of third connecting electrodes CE3, and a plurality of fourth connecting electrodes CE4. The display panel DP may include a first contact electrode CTE1, a second contact electrode CTE2, a sealing member SM, a filling member FM, a first dam structure DAM1, and a second dam structure DAM2.

The plurality of first connecting electrodes CE1 may be located corresponding to the plurality of first pad electrodes PE1. In one or more embodiments, the plurality of first connecting electrodes CE1 may electrically connect the plurality of first pad electrodes PE1 and the display panel DP.

The plurality of second connecting electrodes CE2 may be located corresponding to the plurality of second pad electrodes PE2. In one or more embodiments, the plurality of second connecting electrodes CE2 may electrically connect the plurality of second pad electrodes PE2 and the driving controller CON.

The plurality of third connecting electrodes CE3 may be located corresponding to the plurality of third pad electrodes PE3. In one or more embodiments, the plurality of third connecting electrodes CE3 may electrically connect the plurality of third pad electrodes PE3 and the display panel DP.

The plurality of fourth connecting electrodes CE4 may be located corresponding to the plurality of fourth pad electrodes PE4. In one or more embodiments, the plurality of fourth connecting electrodes CE4 may electrically connect the plurality of sixth pad electrodes PE6 and the driving controller CON.

In one or more embodiments, the plurality of first to fourth connecting electrodes CE1, CE2, CE3, and CE4 may be conductive tapes. However, the types of the connecting electrodes according to one or more embodiments of the present disclosure may not be limited thereto. For example, the connecting electrodes may include conductive balls.

In one or more embodiments, the first pad area PA1 may include the first contact electrode CTE1 and the second contact electrode CTE2. These electrodes may be electrodes of the display panel DP to be electrically connected to the plurality of first connecting electrodes CE1.

In one or more embodiments, the first contact electrode CTE1 and the second contact electrode CTE2 may contact each other through contact holes penetrating a first insulating layer IL1 in a thickness direction of the base substrate BS (e.g., the third direction DR3). In one or more embodiments, the first contact electrode CTE1 may be arranged in (e.g., at) a same layer as the gate electrode GE. The second contact electrode CTE2 may be arranged in (e.g., at) a same layer as the source electrode SE and the drain electrode DE.

In one or more embodiments, at least one first connecting electrode from among the plurality of first connecting electrodes CE1 may contact the second contact electrode CTE2. For example, at least one first connecting electrode from among the plurality of first connecting electrodes CE1 may be electrically connected to the second contact electrode CTE2 through a contact hole penetrating a second insulating layer IL2 in the thickness direction of the base substrate BS (e.g., the third direction DR3). In one or more embodiments, the structure in which the second connecting electrodes CE2 are connected to the display panel DP may be substantially a same as or similar to the structure in which the first connecting electrodes CE1 are connected to the display panel DP.

In one or more embodiments, in a cross-sectional view, the filling member FM may be arranged between the encapsulation substrate ES and the display panel DP. For example, the filling member FM may cover a color filter CF, a black matrix BM, a third thin film encapsulation layer TFE3, the first dam structure DAM1, the second dam structure DAM2, and the second insulating layer IL2. In a plan view, the filling member FM may be at least partially surrounded by the sealing member SM. The filling member FM may prevent external impurities such as oxygen and/or moisture from penetrating the space between the base substrate BS and the encapsulation substrate ES through the sealing member SM. Additionally, the filling member FM may prevent external impacts from concentrating on the sealing member SM.

In one or more embodiments, the filling member FM may include an organic material. For example, the filling member FM may include one or more of acrylic resin, methacrylic resin, vinyl resin, polyisoprene, epoxy resin, urethane resin, and/or cellulose resin. These may be used alone or in combination. Examples of the acrylic resin may include butyl acrylate and ethylhexyl acrylate. Examples of the methacrylic resin may include propylene glycol methacrylate and tetrahydrofurfuryl methacrylate. Examples of the vinyl resin may include vinyl acetate and N-vinylpyrrolidone. An example of the epoxy resin is cycloaliphatic epoxide. An example of the urethane resin is urethane acrylate. An example of the cellulose resin is cellulose nitrate. However, the present disclosure may not be limited thereto, and the filling member FM may include various organic materials.

The first dam structure DAM1 and the second dam structure DAM2 may be arranged in a non-display area NDA. For example, they may be arranged on the second insulating layer IL2 in the non-display area NDA. In one or more embodiments, the first and second dam structures DAM1 and DAM2 may be formed in (e.g., at) a same layer as the pixel defining layer PDL. For example, they may include a same material as the pixel defining layer PDL and may be formed through a same process. However, the dam structures according to one or more embodiments of the present disclosure may not be limited thereto. For example, the dam structures may have a multilayer structure or may include a layer formed in a same layer as at least one from among the first and second insulating layers IL1 and IL2. In the present disclosure, the first and second dam structures DAM1 and DAM2 may be referred to as a first dam structure.

In one or more embodiments, the dam structures DAM1 and DAM2 may prevent the filling member FM from flowing out of the display panel DP. The first thin film encapsulation layer TFE1 and the third thin film encapsulation layer TFE3 may extend from the display area DA to the first dam structure DAM1. These layers may not be formed on the second dam structure DAM2. However, the number and arrangement of dam structures according to one or more embodiments of the present disclosure are merely illustrative and may not be limited thereto.

In one or more embodiments, in a cross-sectional view, the sealing member SM may be arranged between the display panel DP and the encapsulation substrate ES. For example, the sealing member SM may bond the display panel DP and the encapsulation substrate ES to each other in the non-display area NDA. The sealing member SM may contact both the encapsulation substrate ES and the display panel DP. In one or more other embodiments, the sealing member SM may contact both the transparent substrate TS and the display panel DP. In a plan view, the sealing member SM may be around (e.g., may surround) at least a portion of the display area DA.

In one or more embodiments, the sealing member SM may include an organic material. For example, the sealing member SM may include one or more of acrylic resin, methacrylic resin, vinyl resin, polyisoprene, epoxy resin, urethane resin, and/or cellulose resin. These may be used alone or in combination. Examples of the acrylic resin may include butyl acrylate and ethylhexyl acrylate. Examples of the methacrylic resin may include propylene glycol methacrylate and tetrahydrofurfuryl methacrylate. Examples of the vinyl resin may include vinyl acetate and N-vinylpyrrolidone. An example of the epoxy resin is cycloaliphatic epoxide. An example of the urethane resin is urethane acrylate. An example of the cellulose resin is cellulose nitrate. However, the present disclosure may not be limited thereto, and the sealing member SM may include various materials.

The number, shape, and stacking structure of the dam structures included in the display panel DP according to one or more embodiments of the present disclosure are merely illustrative and may not be limited thereto. Also, the structure in which the display panel DP and the driving controller CON are mounted on the transparent substrate TS according to one or more embodiments of the present disclosure is illustrative and may not be limited thereto.

As described above and also referring to FIGS. 1, 2, 3, 4, 5, 6, 7, 8, 9, and 10, in the display device DD according to one or more embodiments of the present disclosure, the driving controller CON and the display panel DP may be arranged on the one surface of the transparent substrate TS. The driving controller CON and the display panel DP may be spaced (e.g., spaced apart) in a plan view and electrically connected to each other through a plurality of connecting lines CL arranged on the one surface of the transparent substrate TS. Accordingly, the display device DD may allow the driving controller CON to be arranged without a size constraint to achieve high resolution. Also, the display area DA in which the pixels PX are arranged may be reduced, and the dead space that causes spatial restrictions in pixel PX arrangement may be reduced or minimized. Therefore, image degradation caused by the size constraint of the driving controller CON may be reduced, and as a result of implementing a high-resolution display device DD, display quality may be improved.

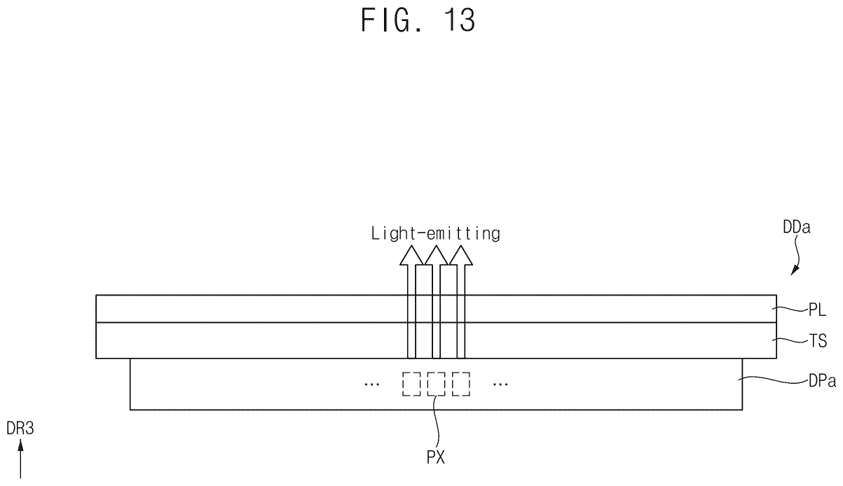

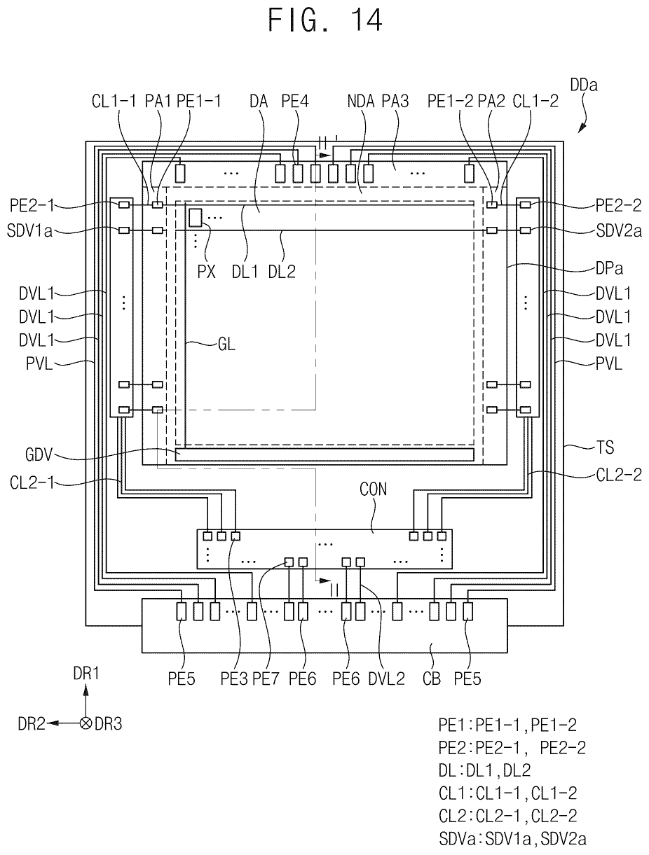

FIG. 13 is a cross-sectional view illustrating a stacked structure of a display device according to one or more embodiments of the present disclosure. FIG. 14 is a bottom view illustrating an example of a bottom surface of the display device of FIG. 13.

Referring to FIGS. 13 and 14, a display device DDa may be substantially the same as or similar to the display device DD described with reference to FIGS. 3 and 5, except that the encapsulation substrate ES of FIG. 3 is not included and a source driver SDV is not included in the display panel DPa. Hereinafter, descriptions that overlap with those described with reference to FIGS. 3 and 5 may be omitted or briefly explained.

Referring to FIGS. 13 and 14, the display device DDa according to one or more embodiments of the present disclosure may include a display panel DPa, a transparent substrate TS, and a protective layer PL. In other words, an encapsulation substrate may not be further provided between the display panel DPa and the transparent substrate TS. Accordingly, a thickness of the display device DDa in FIG. 13 may be relatively less than a thickness of the display device DD in FIG. 1.

In one or more embodiments, the display device DDa may further include a source driver SDVa, a plurality of first-first pad electrodes PE1-1, a plurality of first-second pad electrodes PE1-2, a plurality of second-first pad electrodes PE2-1, a plurality of second-second pad electrodes PE2-2, a plurality of third pad electrodes PE3, a plurality of fourth pad electrodes PE4, a plurality of fifth pad electrodes PE5, a plurality of sixth pad electrodes PE6, a plurality of seventh pad electrodes PE7, a plurality of first-first connecting lines CL1-1, a plurality of first-second connecting lines CL1-2, a plurality of second-first connecting lines CL2-1, a plurality of second-second connecting lines CL2-2, a power line PVL, a plurality of first driving lines DVL1, and a plurality of second driving lines DVL2. In this disclosure, the plurality of first-first and first-second connecting lines CL1-1 and CL1-2 may be collectively referred to as a plurality of first connecting lines, and the plurality of second-first and second-second connecting lines CL2-1 and CL2-2 may be collectively referred to as a plurality of second connecting lines.

The source driver SDVa may include a first source driver SDV1a and a second source driver SDV2a. The source driver SDVa may be arranged on the one surface of the transparent substrate TS. For example, the first source driver SDV1a and the second source driver SDV2a may be spaced (e.g., spaced apart) from the display device DDa in a plan view. In other words, the source drivers SDV1a and SDV2a may not be mounted within the display device DDa.

The display device DDa may include a first pad area PA1, a second pad area PA2, a third pad area PA3, a display area DA, and a non-display area NDA. In one or more embodiments, in a plan view, the display area DA and the non-display area NDA may be arranged between the first pad area PA1 and the second pad area PA2. The first pad area PA1, the second pad area PA2, and the non-display area NDA may be adjacent to the third pad area PA3.

In one or more embodiments, a gate driver GDV may be arranged between the plurality of third pad electrodes PE3 and the display area DA. For example, the gate driver GDV may be arranged in a non-display area NDA positioned in a direction opposite to the first direction DR1 from the display area DA.

In one or more embodiments, in the first pad area PA1 on the one surface of the transparent substrate TS, a plurality of first-first pad electrodes PE1-1 may be arranged. The plurality of first-first pad electrodes PE1-1 may be arranged along the first direction DR1. Each of the plurality of first-first pad electrodes PE1-1 may be spaced (e.g., spaced apart) from each other in a plan view along the first direction DR1. The plurality of first-first pad electrodes PE1-1 may be electrically connected to the display panel DP. The first-first pad electrodes PE1-1 may be electrically connected to each of the first source driver SDV1a, the second source driver SDV2a, and the gate driver GDV.

In one or more embodiments, in the second pad area PA2 on the one surface of the transparent substrate TS, a plurality of first-second pad electrodes PE1-2 may be arranged. The plurality of first-second pad electrodes PE1-2 may also be arranged along the first direction DR1. Each of the first-second pad electrodes PE1-2 may be spaced (e.g., spaced apart) from each other in a plan view along the first direction DR1. The first-second pad electrodes PE1-2 may be electrically connected to the display panel DP. The first-second pad electrodes PE1-2 may be electrically connected to each of the first source driver SDV1, the second source driver SDV2, and the gate driver GDV.

The plurality of first-first pad electrodes PE1-1 may be electrodes to be electrically connected to the first source driver SDV1a, and the plurality of first-second pad electrodes PE1-2 may be electrodes to be electrically connected to the second source driver SDV2a.

In one or more embodiments, the first source driver SDV1a may be adjacent to the first pad area PA1. For example, the first source driver SDV1a may be located in a second direction DR2 from the first pad area PA1. Similarly, the second source driver SDV2a may be adjacent to the second pad area PA2 and located in the second direction DR2 from the second pad area PA2.

The plurality of second-first pad electrodes PE2-1 may be arranged on the one surface of the transparent substrate TS. For example, the plurality of second-first pad electrodes PE2-1 may overlap the first source driver SDV1a on the transparent substrate TS. In one or more embodiments, the plurality of second-first pad electrodes PE2-1 may be arranged along the first direction DR1, and each of the second-first pad electrodes PE2-1 may be spaced (e.g., spaced apart) from each other in a plan view along the first direction DR1. The second-first pad electrodes PE2-1 may be electrically connected to the first source driver SDV1a.

The plurality of second-second pad electrodes PE2-2 may be arranged on the one surface of the transparent substrate TS. For example, the plurality of second-second pad electrodes PE2-2 may overlap the second source driver SDV2a on the transparent substrate TS. In one or more embodiments, the second-second pad electrodes PE2-2 may be arranged along the first direction DR1 and may be spaced (e.g., spaced apart) from each other in the plan view along the first direction DR1. The second-second pad electrodes PE2-2 may be electrically connected to the second source driver SDV2a.

The plurality of second-first pad electrodes PE2-1 may be arranged corresponding to the plurality of first-first pad electrodes PE1-1, and the plurality of second-second pad electrodes PE2-2 may be arranged corresponding to the plurality of first-second pad electrodes PE1-2. The second-first and second-second pad electrodes PE2-1 and PE2-2 may be electrodes to be electrically connected to the display panel DP.

In one or more embodiments, the plurality of first-first connecting lines CL1-1 may extend from the first source driver SDV1a toward the display panel DP. For example, the plurality of first-first connecting lines CL1-1 may extend to the first pad area PA1. The plurality of first-first connecting lines CL1-1 may electrically connect the first-first pad electrodes PE1-1 and the second-first pad electrodes PE2-1.

In one or more embodiments, the plurality of first-second connecting lines CL1-2 may extend from the second source driver SDV2a toward the display panel DP. For example, the plurality of first-second connecting lines CL1-2 may extend to the second pad area PA2. The first-second connecting lines CL1-2 may electrically connect the first-second pad electrodes PE1-2 and the second-second pad electrodes PE2-2.

The plurality of third pad electrodes PE3 may be arranged on the one surface of the transparent substrate TS. For example, the plurality of third pad electrodes PE3 may overlap the driver controller CON in a plan view on a same surface of the transparent substrate TS. In one or more embodiments, the third pad electrodes PE3 may be electrically connected to the driver controller CON. The third pad electrodes PE3 may be electrodes to be electrically connected to each of the first source driver SDV1a and the second source driver SDV2a.

The plurality of second-first connecting lines CL2-1 may be arranged on the one surface of the transparent substrate TS. In one or more embodiments, the second-first connecting lines CL2-1 may extend from the driver controller CON toward the first source driver SDV1a. For example, the second-first connecting lines CL2-1 may electrically connect the driver controller CON and the first source driver SDV1a, and may also electrically connect the first-first pad electrodes PE1-1 and the second-first pad electrodes PE2-1. In one or more embodiments, the second-first connecting lines CL2-1 may electrically connect the third pad electrodes PE3 and the second-first pad electrodes PE2-1 to each other.

The plurality of second-second connecting lines CL2-2 may also be arranged on the one surface of the transparent substrate TS. In one or more embodiments, the second-second connecting lines CL2-2 may extend from the driver controller CON toward the second source driver SDV2a. For example, the second-second connecting lines CL2-2 may electrically connect the driver controller CON and the second source driver SDV2a, and may also electrically connect the first-second pad electrodes PE1-2 and the second-second pad electrodes PE2-2. In one or more embodiments, the second-second connecting lines CL2-2 may electrically connect the third pad electrodes PE3 and the first-second pad electrodes PE1-2 to each other.

The plurality of fourth pad electrodes PE4 may be arranged on the one surface of the transparent substrate TS. For example, the fourth pad electrodes PE4 may be arranged in the third pad area PA3. In one or more embodiments, the fourth pad electrodes PE4 may be arranged along a second direction DR2, and each of the fourth pad electrodes PE4 may be spaced (e.g., spaced apart) in the second direction DR2. The fourth pad electrodes PE4 may be electrically connected to the display panel DP and may serve as electrodes to be electrically connected to a circuit board CB. In one or more embodiments, the fourth pad electrodes PE4 may be electrically connected to each of the first source driver SDV1a, the second source driver SDV2a, and the gate driver GDV.

The plurality of fifth pad electrodes PE5 may be arranged on the one surface of the transparent substrate TS. The fifth pad electrodes PE5 may overlap the circuit board CB in a plan view on a same surface of the transparent substrate TS. In one or more embodiments, the fifth pad electrodes PE5 may be arranged along the second direction DR2, and each of the fifth pad electrodes PE5 may be spaced (e.g., spaced apart) along the second direction DR2. The fifth pad electrodes PE5 may be electrically connected to the circuit board CB and may serve as electrodes to be electrically connected to the display panel DP.

A power line PVL may be arranged on the one surface of the transparent substrate TS. In one or more embodiments, the power line PVL may extend from the circuit board CB toward the display panel DP. For example, the power line PVL may extend toward the third pad area PA3.

The power line PVL may electrically connect a fifth pad electrode PE5 located at one end of the circuit board CB among the plurality of fifth pad electrodes PE5 and a fourth pad electrode PE4 located at a central portion of the third pad area PA3 from among the plurality of fourth pad electrodes PE4. However, the connecting method of the power line PVL according to one or more embodiments of the present disclosure may not be limited thereto.

In one or more embodiments, the power line PVL extending from a fifth pad electrode PE5 located at an end of the circuit board CB in the second direction DR2 among the plurality of fifth pad electrodes PE5 may be around (e.g., may surround) at least a portion of the display panel DP and the first source driver SDV1a. In another embodiment, the power line PVL extending from a fifth pad electrode located at the opposite end of the circuit board CB in the second direction DR2 may be around (e.g., may surround) at least a portion of the display panel DP and the second source driver SDV2a.

The plurality of first driving lines DVL1 may be arranged on the one surface of the transparent substrate TS. In one or more embodiments, the first driving lines DVL1 may extend from the circuit board CB toward the display panel DP. For example, the first driving lines DVL1 may extend to the third pad area PA3. The first driving lines DVL1 may electrically connect the fifth pad electrodes PE5 and the fourth pad electrodes PE4.

In one or more embodiments, a portion of the first driving lines DVL1 may be around (e.g., may surround) at least a portion of the first source driver SDV1a in a plan view. The remaining first driving lines DVL1 may be around (e.g., may surround) at least a portion of the second source driver SDV2a in a plan view.

The plurality of sixth pad electrodes PE6 may be arranged on the one surface of the transparent substrate TS. For example, the sixth pad electrodes PE6 may overlap the circuit board CB in a plan view on the surface of the transparent substrate TS. In one or more embodiments, the sixth pad electrodes PE6 may be electrically connected to the circuit board CB. The sixth pad electrodes PE6 may serve as electrodes to be electrically connected to the driver controller CON. In one or more embodiments, the sixth pad electrodes PE6 may be arranged along a second direction DR2, and each of the sixth pad electrodes PE6 may be spaced (e.g., spaced apart) in the second direction DR2.

The plurality of seventh pad electrodes PE7 may also be arranged on the one surface of the transparent substrate TS. For example, the seventh pad electrodes PE7 may overlap the driver controller CON in a plan view on the surface of the transparent substrate TS. In one or more embodiments, the seventh pad electrodes PE7 may be electrically connected to the driver controller CON and may serve as electrodes to be electrically connected to the circuit board CB. The seventh pad electrodes PE7 may be arranged along the second direction DR2, and each of the seventh pad electrodes PE7 may be spaced (e.g., spaced apart) in the second direction DR2.

The plurality of second driving lines DVL2 may be arranged on the one surface of the transparent substrate TS. In one or more embodiments, the second driving lines DVL2 may extend from the circuit board CB toward the driver controller CON. For example, the second driving lines DVL2 may electrically connect the sixth pad electrodes PE6 and the seventh pad electrodes PE7.

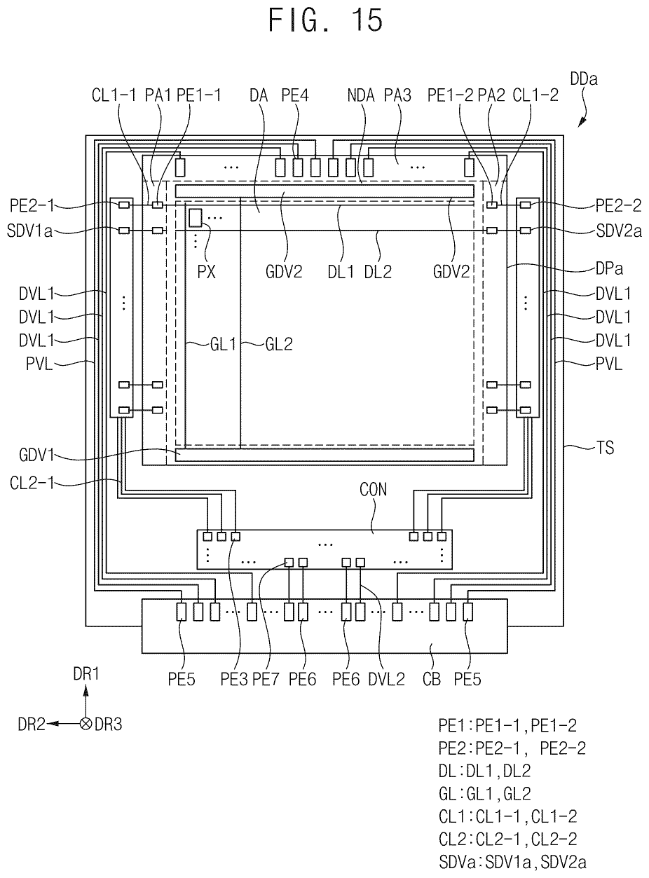

FIG. 15 is a bottom view illustrating another example of a bottom surface of the display device of FIG. 13.

Referring to FIG. 15, a display device DDa may be substantially a same as or similar to the display device DDa described with reference to FIG. 14, except for a first gate driver GDV1, a second gate driver GDV2, a plurality of first gate lines GL1, and a plurality of second gate lines GL2. Hereinafter, descriptions that overlap with those described with reference to FIG. 14 may be omitted or briefly explained.

Referring to FIG. 15, the gate driver GDV included in the display panel DPa may include a first gate driver GDV1 and a second gate driver GDV2. In one or more embodiments, the first gate driver GDV1 and the second gate driver GDV2 may be spaced (e.g., spaced apart) from each other in a plan view. Specifically, the first gate driver GDV1 may be arranged in a non-display area NDA located between the plurality of third pad electrodes PE3 and the display area DA in a plan view. The second gate driver GDV2 may be arranged in a non-display area DA located between the third pad area PA3 and the display area DA in a plan view.

A plurality of gate lines GL of the display panel DP may include a plurality of first gate lines GL1 and a plurality of second gate lines GL2. The first gate lines GL1 and the second gate lines GL2 may be spaced (e.g., spaced apart) from each other in a second direction DR2. In one or more embodiments, one first gate line from among the first gate lines GL1 and one second gate line from among the second gate lines GL2 may be alternately arranged along the second direction DR2.

In one or more embodiments, each of the plurality of first gate lines GL1 may be electrically connected to the first gate driver GDV1. For example, each of the first gate lines GL1 may extend from the first gate driver GDV1 in a first direction DR1 and be electrically connected to each of the plurality of pixels PX. In one or more embodiments, each of the second gate lines GL2 may be electrically connected to the second gate driver GDV2. For example, each of the second gate lines GL2 may extend from the second gate driver GDV2 in a direction opposite to the first direction DR1 and may be electrically connected to each of the plurality of pixels PX.

In one or more embodiments, the first-first pad electrodes PE1-1 may be electrically connected to each of the first source driver SDV1a, the second source driver SDV2a, the first gate driver GDV1, and the second gate driver GDV2. In one or more embodiments, the first-second pad electrodes PE1-2 may be electrically connected to each of the first source driver SDV1a, the second source driver SDV2a, the first gate driver GDV1, and the second gate driver GDV2. In one or more embodiments, the fourth pad electrodes PE4 may be electrically connected to each of the first source driver SDV1a, the second source driver SDV2a, the first gate driver GDV1, and the second gate driver GDV2.

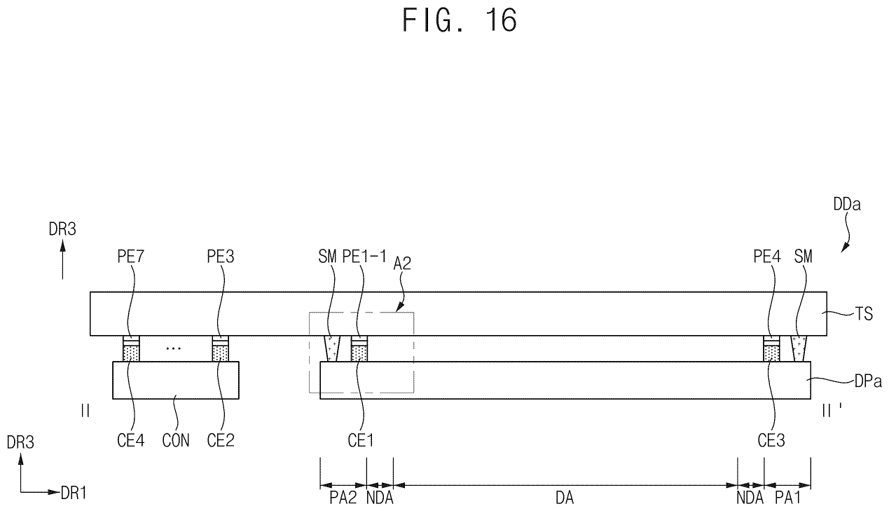

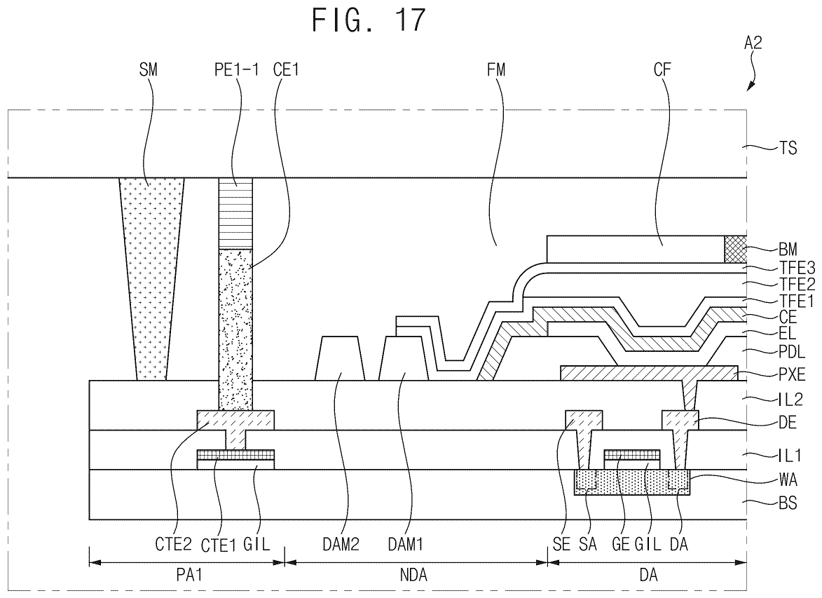

FIG. 16 is a cross-sectional view illustrating a cross-section taken along the line II-II′ of FIG. 14. FIG. 17 is a cross-sectional view illustrating an example of an enlarged view of an area A2 of FIG. 16.

Referring to FIGS. 16 and 17, the display device DDa may be substantially the same as or similar to the display device DD described with reference to FIGS. 11 and 12, except for the arrangement of the sealing member SM and the absence of the encapsulation substrate ES shown in FIGS. 11 and 12. Hereinafter, descriptions that overlap with those described with reference to FIGS. 11 and 12 may be omitted or briefly explained.

Referring to FIGS. 16 and 17, in one or more embodiments, the plurality of first connecting electrodes CE1 may electrically connect the plurality of first-first pad electrodes PE1-1 and the display panel DPa. The plurality of second connecting electrodes CE2 may electrically connect the plurality of third pad electrodes PE3 and the driving controller CON to each other. The plurality of third connecting electrodes CE3 may electrically connect the plurality of fourth pad electrodes PE4 and the display panel DPa. The plurality of fourth connecting electrodes CE4 may electrically connect the plurality of seventh pad electrodes PE7 and the driving controller CON to each other.

In one or more embodiments, in a cross-sectional view, the sealing member SM may be arranged between the transparent substrate TS and the display panel DPa. For example, the sealing member SM may be arranged in the first pad area PA1 and the second pad area PA2, and in a plan view, may surround at least a portion of the display area DA. The sealing member SM may be in contact with both the transparent substrate TS and the display panel DPa. The sealing member SM may bond the transparent substrate TS and the display panel DPa. The plurality of first-first pad electrodes PE1-1 and the plurality of first connecting electrodes CE1 may be located closer to the display area DA than the sealing member SM.

In one or more embodiments, the display panel DPa may include a first dam structure DAM1 and a second dam structure DAM2. The first dam structure DAM1 and the second dam structure DAM2 may prevent the filling member FM from leaking outside the display panel DPa. The first and second dam structures DAM1 and DAM2 may include an organic insulating material. However, the material included in the dam structures and the number of dam structures included in the display panel DPa according to one or more embodiments of the present disclosure may not be limited thereto. In this disclosure, the first and second dam structures DAM1 and DAM2 may be collectively referred to as a first dam structure.

As described above, and further referring to FIGS. 13-15, in a display device DDa according to one or more embodiments of the present disclosure, the driver controller CON and the display panel DPa may be arranged on the one surface of the transparent substrate TS. The driver controller CON and the display panel DPa may be spaced (e.g., spaced apart) from each other in a plan view and may be electrically connected through the plurality of first connecting lines CL1 (CL1-1, CL1-2) and the second connecting lines CL2 (CL2-1 and CL2-2) arranged on the surface of the transparent substrate TS. Accordingly, the display device DDa may allow the driving controller CON to be arranged without a size constraint to achieve high resolution. The display area DA in which pixels PX are arranged may be reduced, and dead space that limits the arrangement of pixels PX may be reduced. Therefore, degradation caused by the size constraint of the driving controller CON may be reduced, and the display quality may be improved by implementing a high-resolution display device DDa.

Furthermore, the encapsulation substrate (e.g., the encapsulation substrate ES in FIG. 3) may not be arranged between the display panel DPa and the transparent substrate TS. Instead, the sealing member SM may be arranged between the display panel DPa and the transparent substrate TS. Accordingly, the thickness of the display device DDa may be less than that of a display device including an encapsulation substrate. Therefore, the manufacturing time and cost of the display device may be reduced.

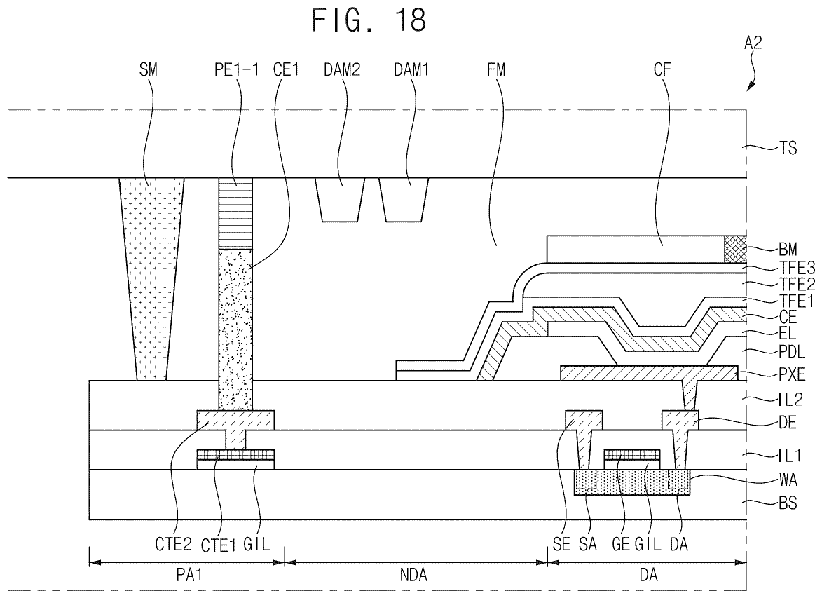

FIG. 18 is a cross-sectional view illustrating another example of an enlarged view of an area A2 of FIG. 16.

Referring to FIG. 18, in one or more embodiments, a first dam structure DAM1 and a second dam structure DAM2 may be arranged on the one surface of the transparent substrate TS. For example, the first dam structure DAM1 and the second dam structure DAM2 may be arranged on the surface of the transparent substrate TS to correspond to the non-display area NDA of the display panel DPa. The first dam structure DAM1 and the second dam structure DAM2 may prevent the filling member FM from leaking outside the display panel DPa. In one or more embodiments, the first dam structure DAM1 and the second dam structure DAM2 may include an organic insulating material. However, the material included in the first and second dam structures DAM1 and DAM2 and the number of dam structures arranged on the surface of the transparent substrate TS according to one or more embodiments of the present disclosure may not be limited thereto. In the present disclosure, the first dam structure DAM1 and the second dam structure DAM2 may be referred to as a second dam structure.

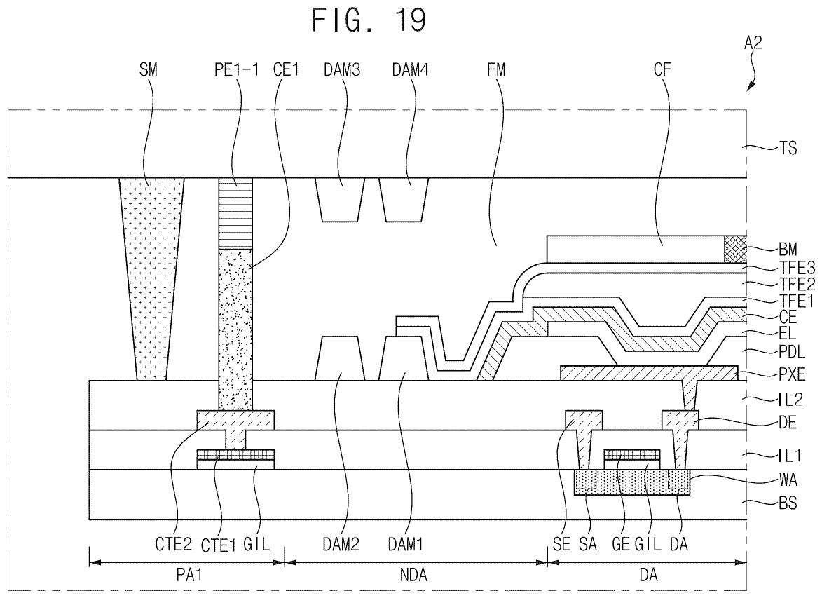

FIG. 19 is a cross-sectional view illustrating still another example of an enlarged view of an area A2 of FIG. 16.

The display device described with reference to FIG. 19 may be substantially the same as or similar to the display device described with reference to FIG. 17, except for the arrangement of a third dam structure DAM3 and a fourth dam structure DAM4. Hereinafter, descriptions overlapping with those provided with reference to FIG. 17 may be omitted or briefly explained.

Referring to FIG. 19, in one or more embodiments, the display panel DPa may include a first dam structure DAM1 and a second dam structure DAM2. The first and second dam structures DAM1 and DAM2 may prevent the filling member FM from leaking outside the display panel DPa. In one or more embodiments, the first dam structure DAM1 and the second dam structure DAM2 may include an organic insulating material. However, the material included in the first and second dam structures DAM1 and DAM2, and the number of dam structures included in the display panel DPa according to one or more embodiments of the present disclosure, may not be limited thereto. In the present disclosure, the first dam structure DAM1 and the second dam structure DAM2 may be referred to as a first dam structure.

In one or more embodiments, a third dam structure DAM3 and a fourth dam structure DAM4 may be arranged on the one surface of the transparent substrate TS. For example, the third dam structure DAM3 and the fourth dam structure DAM4 may be arranged on the surface of the transparent substrate TS to correspond to the non-display area NDA of the display panel DPa. The third and fourth dam structures DAM3 and DAM4 may prevent the filling member FM from leaking outside the display panel DPa. In one or more embodiments, the third dam structure DAM3 and the fourth dam structure DAM4 may include an organic insulating material. However, the material included in the third and fourth dam structures DAM3 and DAM4, and the number of dam structures arranged on the surface of the transparent substrate TS according to one or more embodiments of the present disclosure, may not be limited thereto. In the present disclosure, the third dam structure DAM3 and the fourth dam structure DAM4 may be referred to as a second dam structure.

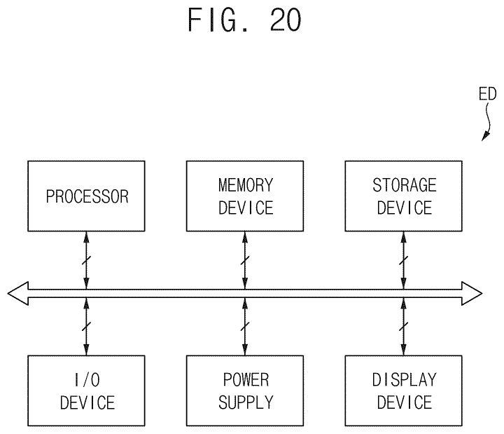

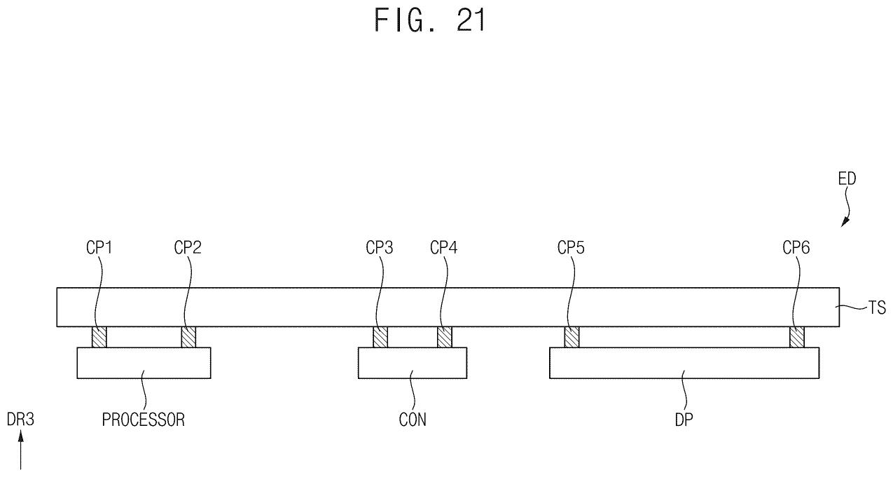

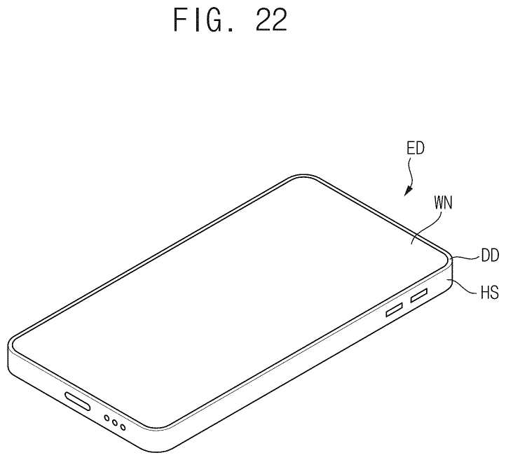

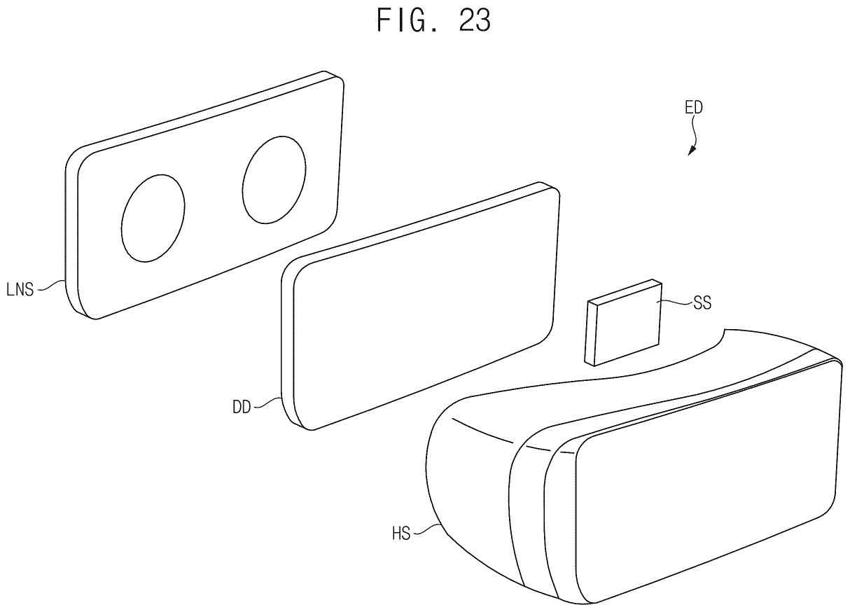

FIG. 20 is a block diagram illustrating an electronic device according to one or more embodiments of the present disclosure. FIG. 21 is a cross-sectional view illustrating a portion of the electronic device of FIG. 20. FIG. 22 is a diagram illustrating an example in which the electronic device of FIG. 20 is implemented as a smartphone. FIG. 23 is a diagram illustrating an example in which the electronic device of FIG. 20 is implemented as a head-mounted device.

Referring to FIG. 20, an electronic device ED may include a processor, a memory device, a storage device, an input/output device, a power supply, and a display device. The display device included in the electronic device ED may be the display device DD of FIG. 1 or the display device DDa of FIG. 13. In addition, the electronic device ED may further include various ports capable of communicating with components such as a video card, a sound card, a memory card, and/or a USB device, or capable of communicating with other systems.

The processor may perform specific calculations or tasks. Depending on the embodiment, the processor may be a microprocessor, a central processing unit (CPU), and/or an application processor. The processor may be connected to other components through an address bus, a control bus, a data bus, and/or the like. In one or more embodiments, the processor may also be connected to an expansion bus such as a Peripheral Component Interconnect (PCI) bus. The processor may output input control signals and input image data (e.g., the input control signal CONT and input image data IMG of FIG. 1) to the driver controller (e.g., the driver controller CON of FIG. 1).

The memory device may store data necessary for operating the electronic device ED. For example, the memory device may include nonvolatile memory devices such as an erasable programmable read-only memory (EPROM), an electrically erasable programmable read-only memory (EEPROM), a flash memory device, a phase change RAM (PRAM), a resistance RAM (RRAM), a nano floating gate memory (NFGM), a polymer RAM (PoRAM), a magnetic RAM (MRAM), a ferroelectric RAM (FRAM), and/or volatile memory devices such as dynamic RAM (DRAM), static RAM (SRAM), and/or mobile DRAM.

The storage device may include a solid state drive (SSD), a hard disk drive (HDD), a CD-ROM, and/or the like. The input/output device may include input means such as a keyboard, keypad, touchpad, touchscreen, and/or mouse, and output means such as a speaker and/or a printer. In one or more embodiments, the display device may be included in the input/output device. The power supply may supply power required for operating the electronic device ED. The display device may be connected to other components via the buses or other communication links.

Referring to FIGS. 20 and 21, the electronic device ED may include a processor, a driver controller CON, a display panel DP, a transparent substrate TS, a first connector CP1, a second connector CP2, a third connector CP3, a fourth connector CP4, a fifth connector CP5, and a sixth connector CP6. The driver controller CON, the display panel DP, and the transparent substrate TS may be included in the display device of FIG. 1 (DD), FIG. 13 (DDa), or the display device of FIG. 20. The display panel DP may be the display panel DP of FIG. 3 or the display panel DPa of FIG. 13.

In one or more embodiments, the processor may be arranged on the one surface of the transparent substrate TS. For example, the processor may be arranged on said surface of the transparent substrate TS alongside the driver controller CON and the display panel DP. In one or more embodiments, the processor may be spaced (e.g., spaced apart) from each of the driver controller CON and the display panel DP in a plan view.

In one or more embodiments, the processor may be electrically connected to the driver controller CON through the first connector CP1 and the second connector CP2. Specifically, a plurality of connecting lines may be arranged on the one surface of the transparent substrate TS, and the connecting lines may electrically connect the first connector CP1, the second connector CP2, the third connector CP3, and the fourth connector CP4. Accordingly, the processor may output the input control signal and the input image data to the driver controller CON.

In one or more embodiments, the driver controller CON may be electrically connected through the third connector CP3 and the fourth connector CP4. The display panel DP may be electrically connected through the fifth connector CP5 and the sixth connector CP6.

The third connector CP3 may correspond to the fourth connecting electrodes CE4 and the sixth pad electrodes PE6 of FIG. 11, or the fourth connecting electrodes CE4 and the seventh pad electrodes PE7 of FIG. 16.

The fourth connector CP4 may correspond to the second connecting electrodes CE2 and the second pad electrodes PE2 of FIG. 11, or the second connecting electrodes CE2 and the third pad electrodes PE3 of FIG. 16.

The fifth connector CP5 may correspond to the first connecting electrodes CE1 and the first pad electrodes PE1 of FIG. 11, or the first connecting electrodes CE1 and the first-first pad electrodes PE1-1 of FIG. 16.

The sixth connector CP6 may correspond to the third connecting electrodes CE3 and the third pad electrodes PE3 of FIG. 11, or the third connecting electrodes CE3 and the fourth pad electrodes PE4 of FIG. 16.

In one or more embodiments, the first connector CP1 and the second connector CP2 may include a conductive material. The first connector CP1 and the second connector CP2 may have substantially a same structure as the third connector CP3, the fourth connector CP4, the fifth connector CP5, and the sixth connector CP6. For example, the first and second connectors CP1 and CP2 may include the same material as, or may be arranged at the same layer as, the third to sixth connectors CP3 to CP6. However, the first and second connectors CP1 and CP2 according to one or more embodiments of the present disclosure may not be limited thereto, and they may have various structures for electrically connecting the processor and the transparent substrate TS.

As described above, in the electronic device ED, the processor and the driver controller CON may be arranged on the one surface of the transparent substrate TS. Accordingly, space for arranging the processor and the driver controller CON inside the electronic device ED may be easily secured. As a result, degradation due to size constraints of the driver controller CON included in the electronic device ED may be reduced, and limitations in arrangement and size of the processor mounted in the electronic device ED may also be reduced.

Referring to FIG. 22, in one or more embodiments, the electronic device ED may be implemented as a smartphone. The electronic device ED may include a cover window WN, a display device DD, and a housing HS. The display device DD may be the display device DD of FIG. 1, the display device DDa of FIG. 13, or the display device of FIG. 20.

The cover window WN may cover the display device DD. For example, the cover window WN may be arranged on the display area (e.g., the display area DA of FIG. 5) of the display device DD to cover the display device DD. Accordingly, the cover window WN may protect the display area of the display device DD where images are displayed.

The housing HS may be around (e.g., may surround) the display device DD. For example, the display device DD may be housed in the housing HS to display images. The housing HS may cover the side and lower portions of the display device DD. Thus, the housing HS may reinforce the mechanical strength of the display device DD and protect the display device DD from external impact.

Functional modules such as a camera module and a sensor module may be housed inside the housing HS. Accordingly, the functional modules may be electrically connected to the display device DD to perform specific functions. However, the types and arrangements of such functional modules according to one or more embodiments of the present disclosure may not be limited thereto.

Referring to FIG. 23, in one or more embodiments, the electronic device ED may be implemented as a head-mounted device. The electronic device ED may include a lens portion LNS, a display device DD, a sensor portion SS, and a housing HS. In one or more embodiments, the electronic device ED may be a virtual reality (VR) device, an augmented reality (AR) device, a mixed reality (MR) device, or an extended reality (XR) device worn on the user's head. The display device DD may be the display device DD of FIG. 1, the display device DDa of FIG. 13, or the display device of FIG. 20.

In one or more embodiments, the sensor portion SS may include a camera, but is not limited thereto and may include various types of sensors capable of tracking the user's gaze. The display device DD may be arranged adjacent to the lens portion LNS. The housing HS may contain the lens portion LNS, the display device DD, and the sensor portion SS. In one or more embodiments, the housing HS may house the processor, memory device, storage device, input/output device, and power supply of FIG. 20. Accordingly, the housing HS may provide the user with a durable electronic device ED.

In FIG. 23, the lens portion LNS, the display device DD, and the sensor portion SS are shown to be housed in one side of the housing HS. However, the electronic device ED according to one or more embodiments of the present disclosure may not be limited thereto. In one or more embodiments, the electronic device ED may further include a strap portion for wearing on the user's head, a cushion portion for improved comfort, and/or the like. Accordingly, the electronic device ED may provide the user with a stable wearing experience.

However, the electronic device ED described with reference to FIGS. 22 and 23 is illustrative, and the type of electronic device ED according to one or more embodiments of the present disclosure may not be limited thereto. For example, the electronic device ED may be implemented as a mobile phone, a videophone, a smart pad, a smart watch, a tablet PC, an in-vehicle display, a computer monitor, or a notebook. The electronic device ED may also be a television, a monitor, a laptop computer, a tablet, and/or an automobile.

The devices according to the embodiments may be applied to a display device included in a computer, a notebook, a mobile phone, a smartphone, a smart pad, a PMP, a PDA, an MP3 player, and/or the like.

Although the devices according to the embodiments have been described with reference to the drawings, the illustrated embodiments are examples, and may be modified and changed by a person having ordinary knowledge in the relevant technical field without departing from the technical spirit described in the following claims and their equivalents.

What is claimed is:

1. A display device comprising:
a transparent substrate;
a display panel located on a one surface of the transparent substrate and including a display area in which a plurality of pixels configured to emit light is arranged, a non-display area adjacent to the display area, and a pad area adjacent to the non-display area;
a driving controller located on the one surface of the transparent substrate, the driving controller being spaced from the display panel and electrically connected to the display panel; and
a plurality of connecting lines located on the one surface of the transparent substrate, the plurality of connecting lines extending from the driving controller toward the display panel and electrically connecting the display panel and the driving controller.

2. The display device of claim 1, wherein the display panel comprises:
a first source driver electrically connected to the driving controller, and located in the non-display area adjacent to one side of the display area; and
a second source driver electrically connected to the driving controller, and located in the non-display area adjacent to an other side of the display area which is opposite to the one side of the display area.

3. The display device of claim 2, further comprising:
a plurality of first pad electrodes located on the one surface of the transparent substrate, overlapping a portion of the display panel located in the pad area in a plan view, and electrically connected to the display panel; and
a plurality of second pad electrodes located on the one surface of the transparent substrate, overlapping the driving controller in a plan view, and electrically connected to the driving controller,
wherein the plurality of connecting lines electrically connects the plurality of first pad electrodes and the plurality of second pad electrodes to each other.

4. The display device of claim 3, wherein the pad area includes:
a first pad area in which the plurality of the first pad electrodes is located; and
a second pad area spaced from the first pad area, wherein the display area and the non-display area are arranged between the first pad area and the second pad area.

5. The display device of claim 4, wherein the display panel further comprises:
a first gate driver electrically connected to the driving controller and located in the non-display area which is located between the first pad area and the display area in a plan view.

6. The display device of claim 5, wherein the display panel further comprises:
a second gate driver electrically connected to the driving controller, located in the non-display area which is located between the second pad area and the display area in a plan view, and spaced from the first gate driver.

7. The display device of claim 5, further comprising:
a plurality of third pad electrodes located on the one surface of the transparent substrate, overlapping a portion of the display panel located in the second pad area, and electrically connected to the display panel;
a circuit board located on the one surface of the transparent substrate and spaced from the display panel and the driving controller in a one direction;
a plurality of fourth pad electrodes located on the one surface of the transparent substrate, overlapping the circuit board in a plan view, and electrically connected to the circuit board;
a plurality of driving lines electrically connecting the plurality of third pad electrodes and the plurality of fourth pad electrodes to each other; and
a power line electrically connecting two fourth pad electrodes from among the plurality of fourth pad electrodes to each other, the two fourth pad electrodes being respectively adjacent to one side and an other side of the circuit board, wherein the power line is configured to provide a first power voltage to the pixels.

8. The display device of claim 7, wherein the plurality of the driving lines comprises:
a first driving line configured to provide a second power voltage having a different voltage level from the first power voltage to the pixels;
a second driving line configured to provide a third power voltage for driving the first source driver and the second source driver; and
a third driving line configured to provide a fourth power voltage for driving the first gate driver.

9. The display device of claim 7, wherein the plurality of the driving lines are spaced from each other in a plan view,
wherein each of the driving lines is around at least a portion of the display panel in a plan view,
wherein the power line is around at least a portion of the plurality of driving lines and the display panel in a plan view.

10. The display device of claim 1, further comprising:
a sealing member located between the display panel and the transparent substrate in a cross-sectional view and surrounding at least a portion of the display area in a plan view; and
an encapsulation substrate located between the display panel and the transparent substrate and combined with the display panel through the sealing member.

11. A display device comprising:
a transparent substrate;
a display panel located on a one surface of the transparent substrate and including a display area in which a plurality of pixels configured to emit light is arranged, a non-display area adjacent to the display area, and a pad area adjacent to the non-display area;
a driving controller located on the one surface of the transparent substrate, spaced from the display panel, and electrically connected to the display panel; and
a source driver located on the one surface of the transparent substrate, spaced from the display panel in a plan view, and electrically connected to the display panel and the driving controller.

12. The display device of claim 11, wherein the source driver comprises:
a first source driver located on the one surface of the transparent substrate, electrically connected to the driving controller, and spaced from one side of the display panel; and
a second source driver located on the one surface of the transparent substrate, electrically connected to the driving controller, and spaced apart from an other side opposite to the one side of the display panel.

13. The display device of claim 12, further comprising:
a circuit board located on the one surface of the transparent substrate and electrically connected to the driving controller and the display panel; and
a plurality of driving lines located on the one surface of the transparent substrate and extending from the circuit board toward the display panel.

14. The display device of claim 13, wherein the pad area includes:
a first pad area adjacent to the first source driver;
a second pad area adjacent to the second source driver; and
a third pad area in which the plurality of driving lines extends.

15. The display device of claim 11, further comprising:
a plurality of first connecting lines located on the one surface of the transparent substrate, extending from the source driver toward the display panel, and electrically connecting the display panel and the source driver; and
a plurality of second connecting lines located on the one surface of the transparent substrate, extending from the driving controller toward the display panel, and electrically connecting the driving controller and the source driver.

16. The display device of claim 11, further comprising:
a sealing member located between the display panel and the transparent substrate in a cross-sectional view and contacting the display panel and the transparent substrate.

17. The display device of claim 16, wherein the display panel further comprises:
a dam structure located closer to the display area than the sealing member, in the non-display area.

18. The display device of claim 16, further comprising:
a dam structure located on the one surface of the transparent substrate and located closer to the display area than the sealing member, in the non-display area.

19. An electronic device comprising:
a processor configured to output an input image data and an input control signal; and
a display device configured to drive based on the input image data and the input control signal,
wherein the display device comprises:
a transparent substrate;
a display panel located on a one surface of the transparent substrate and including a display area in which a plurality of pixels configured to emit light is arranged, a non-display area adjacent to the display area, and a pad area adjacent to the non-display area;
a driving controller configured to receive the input image data and the input control signal, the driving controller being located on the one surface of the transparent substrate, spaced from the display panel, and electrically connected to the display panel; and
a plurality of connecting lines located on the one surface of the transparent substrate and electrically connecting the display panel and the driving controller.

20. The electronic device of claim 19, wherein the processor is located on the one surface of the transparent substrate.
